(19) United States
(12) Patent Application Publication
(10) Pub. No.: US 2025/0294799 A1
(43) Pub. Date: Sep. 18, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/769,518

(22) Filed: Jul. 11, 2024

Related U.S. Application Data
(60) Provisional application No. 63/565,478, filed on Mar. 14, 2024.

(51) Int. Cl. H01L 29/78; H01L 29/06; H01L 29/423; H01L 29/66; H01L 29/775; H01L 29/786

(52) U.S. Cl. CPC H10D 30/6211; H10D 30/014; H10D 30/024; H10D 30/43; H10D 30/6735; H10D 30/6757; H10D 62/121

(57) ABSTRACT

Embodiments of the present disclosure relate to a semiconductor device structure. The structure includes a substrate, an insulating material disposed on the substrate, a first fin structure extending upwardly from the substrate through the insulating material, a second fin structure extending upwardly from the substrate through the insulating material, wherein the first and second fin structures extend along a first direction. The structure further includes an isolation trench structure disposed between the first and second fin structures, the isolation trench structure extending along a second direction perpendicular to the first direction, wherein the isolation trench structure has a bottom in contact with a top surface of the substrate, and the bottom of the isolation trench structure and the top surface of the substrate define an interface that is substantially flat.

### CROSS-REFERENCE TO RELATED APPLICATIONS

This application claims priority to U.S. Provisional Application Ser. No. 63/565,478 filed Mar. 14, 2024, which is incorporated by reference in their entirety.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, continued reduction of the gate pitch is necessary. Various schemes, such as poly on diffusion edge (PODE) and continuous poly on diffusion edge (CPODE), have been used to scale the gate pitch while preventing leakage current between transistors. However, it has been observed that parasitic fin bipolar transistor may form during the etch process, leading to formation of EPI-substrate-EPI leakage path.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-10A are cross-sectional side views of various stages of manufacturing the semiconductor device structure taken along line A-A of FIG. 6, in accordance with some embodiments.

FIGS. 7B-10B are cross-sectional side views of various stages of manufacturing the semiconductor device structure taken along line B-B of FIG. 6, in accordance with some embodiments.

FIGS. 7C-10C are cross-sectional side views of various stages of manufacturing the semiconductor device structure taken along line C-C of FIG. 6, in accordance with some embodiments.

FIGS. 11A-11B to 18A-18B and 21A-21B to 25A-25B are cross-sectional side views of one of various stages of manufacturing the semiconductor device structure of FIGS. 10A and 10B showing multiple fin structures disposed along the X and Y directions, respectively, in accordance with some embodiments.

FIG. 18B-1 illustrates an enlarged view of a portion of the substrate shown in FIG. 18B, in accordance with some embodiments.

FIGS. 19 and 20 illustrate embodiments where the isolation trenches are etched to have a bottom extending a depth into the well region of the substrate, in accordance with some embodiments.

FIG. 19-1 illustrates an enlarged view of a portion of the substrate shown in FIG. 19, in accordance with some embodiments.

FIGS. 26 and 27 illustrate cross-sectional views of the semiconductor device structure, in accordance with the embodiments shown in FIGS. 19 and 20, respectively.

FIG. 28 is a top view of the semiconductor device structure shown in FIGS. 25A and 25B, in accordance with some embodiments.

FIGS. 29A, 29B, 29C are cross-sectional views of the semiconductor device structure taken along line D-D, line E-E, and line F-F of FIG. 28, respectively.

FIGS. 30-36 illustrate an alternative embodiment where a portion of insulating material remains within the isolation trench structure and on the top surface of the exposed substrate, in accordance with some embodiments.

FIGS. 37-43 illustrate an alternative embodiment where a portion of insulating material remains within the isolation trench structure and is disposed away from the top surface of the exposed substrate, in accordance with some embodiments.

FIGS. 44A and 44B to 49A and 49B are cross-sectional views of one of various stages of manufacturing the semiconductor device structure, in accordance with some alternative embodiments.

FIG. 50 is an enlarged view of a portion of the substrate shown in FIG. 49B, in accordance with some embodiments.

FIG. 51 illustrates an embodiment where the isolation trench structures have a bottom at substantially the same elevation as the top surface of the substrate, in accordance with some embodiments.

FIG. 51-1 illustrates an enlarged view of a portion of the substrate shown in FIG. 51, in accordance with some embodiments.

FIG. 52 illustrates a cross-sectional view of the semiconductor device structure, in accordance with an alternative embodiment.

FIG. 53 illustrates a cross-sectional view of the semiconductor device structure in accordance with an alternative embodiment.

FIG. 54 illustrates an enlarged view of a portion of the substrate shown in FIGS. 52 and 53, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated circuit scales down, epitaxial critical dimension (EPI CD), which refers to spacings between epitaxial regions, becomes smaller and smaller. Small EPI CD makes it challenging to etch trenches for insulation structures without damaging adjacent structures, such as epitaxial source/drain features. Exemplary insulation structures may include a Continuous-Poly-On-Diffusion-Edge (CPODE) structure that removes a portion of, or a selected fin structure in its entirety, and replaces with it with an insulating material to form isolation trenches. The CPODE structures avoid leakage current through epitaxial source/drain features, transistors, and silicon substrates. Embodiments of the present disclosure are applicable to other devices which may include CPODE or CMODE structures, such as planar FETs, Fin-FETs, Horizontal Gate All Around (HGAA) FETs, Vertical Gate All Around (VGAA) FETs, and other suitable devices.

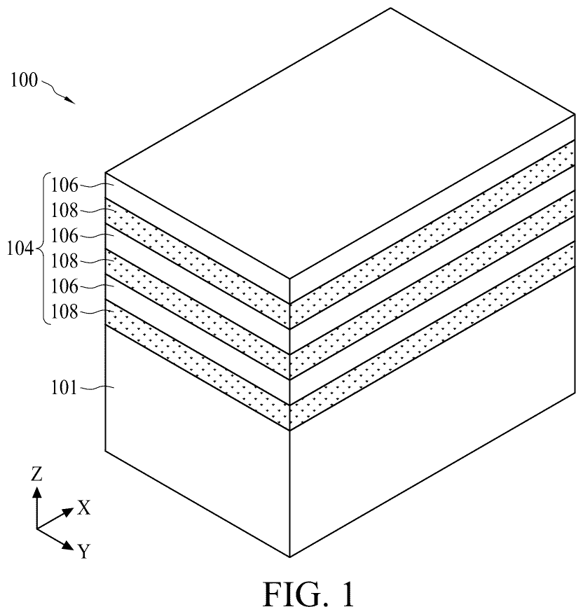

FIGS. 1 to 54 show exemplary processes for manufacturing a semiconductor device structure 100 according to embodiments of the present disclosure. It is understood that additional operations can be provided before, during, and after processes shown by FIGS. 1 to 54, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-well region and boron for a p-well region.

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof. In some embodiments, the second semiconductor layers 108 may be etched and replaced by other materials, such as SiO or SiN, during the processes.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

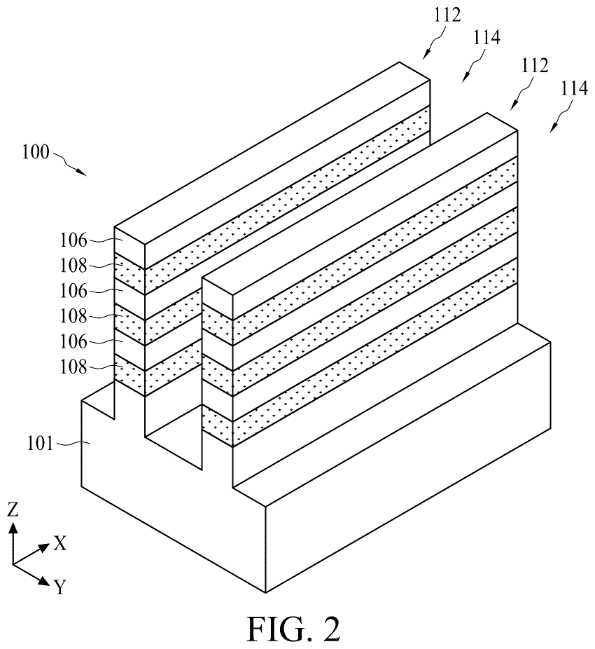

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof. In some embodiments, each fin structure 112 has a longitudinal axis along the X direction.

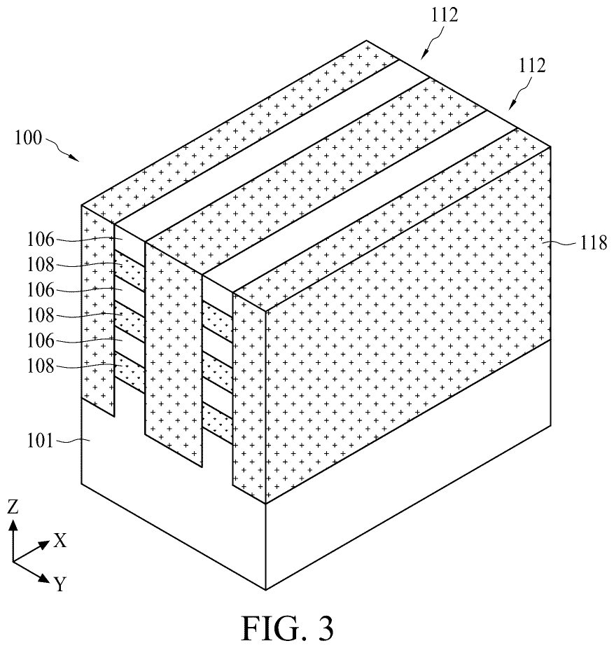

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be a multi-layer dielectric structure. The insulating material 118 may be formed by any suitable method, such as low-pressure chemical vapor deposition (LPCVD), plasma enhanced CVD (PECVD) or flowable CVD (FCVD).

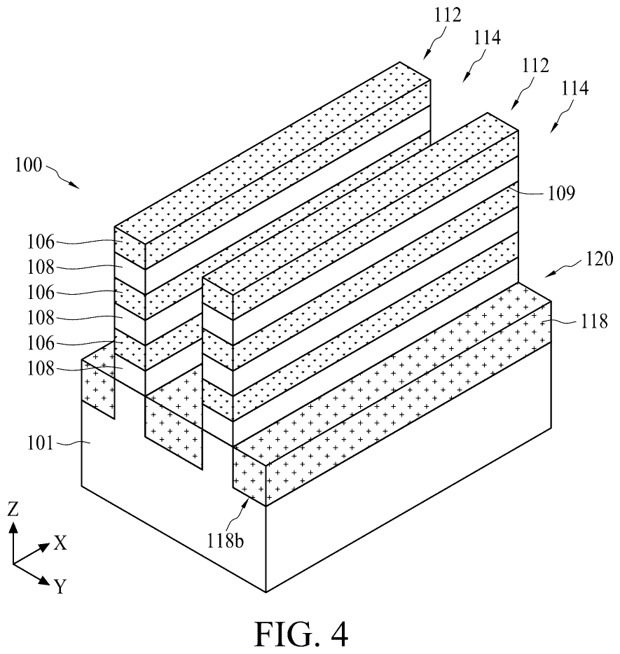

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

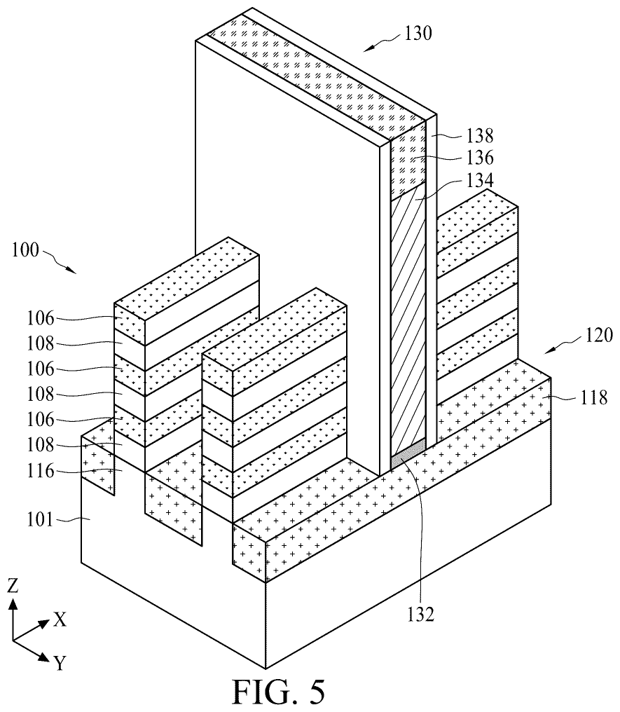

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on the sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

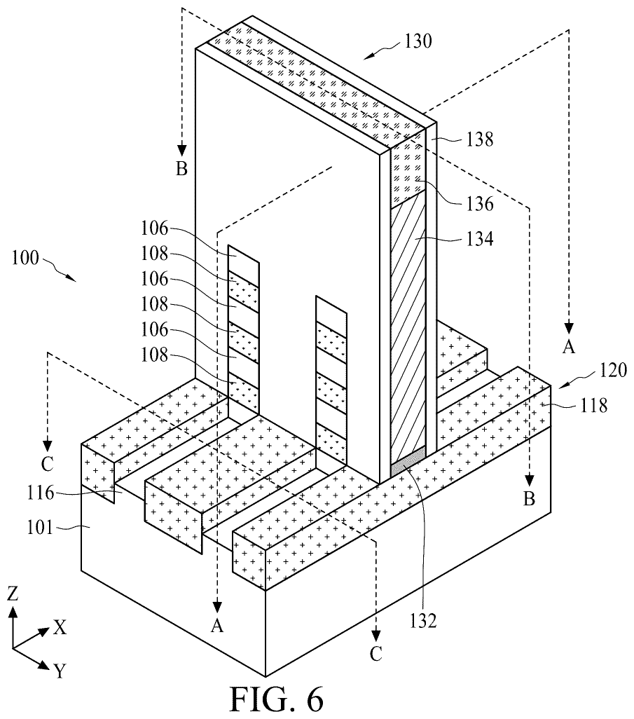

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

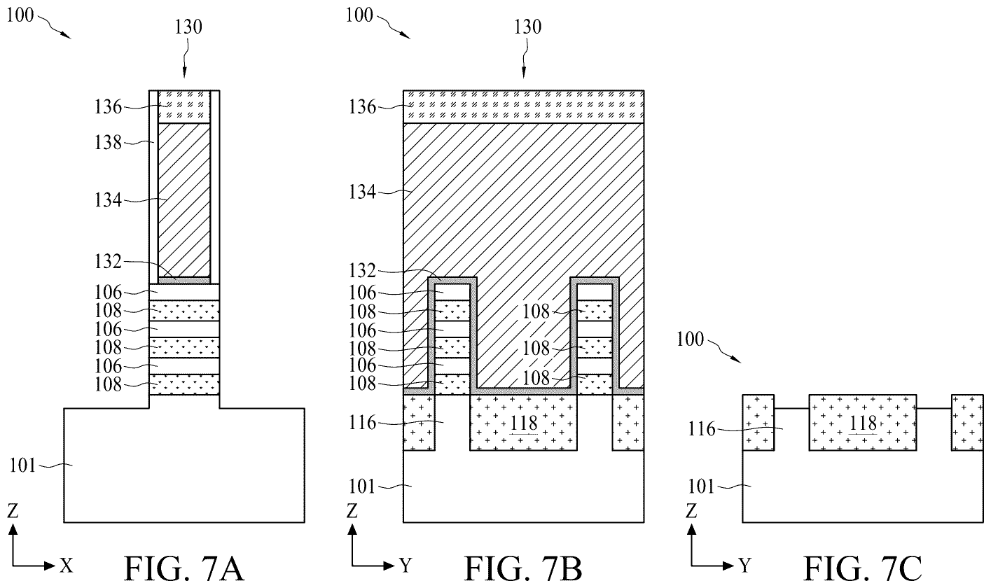

FIGS. 7A, 7B, and 7C are cross-sectional side views of the semiconductor device structure 100 taken along line A-A, line B-B, and line C-C of FIG. 6, respectively.

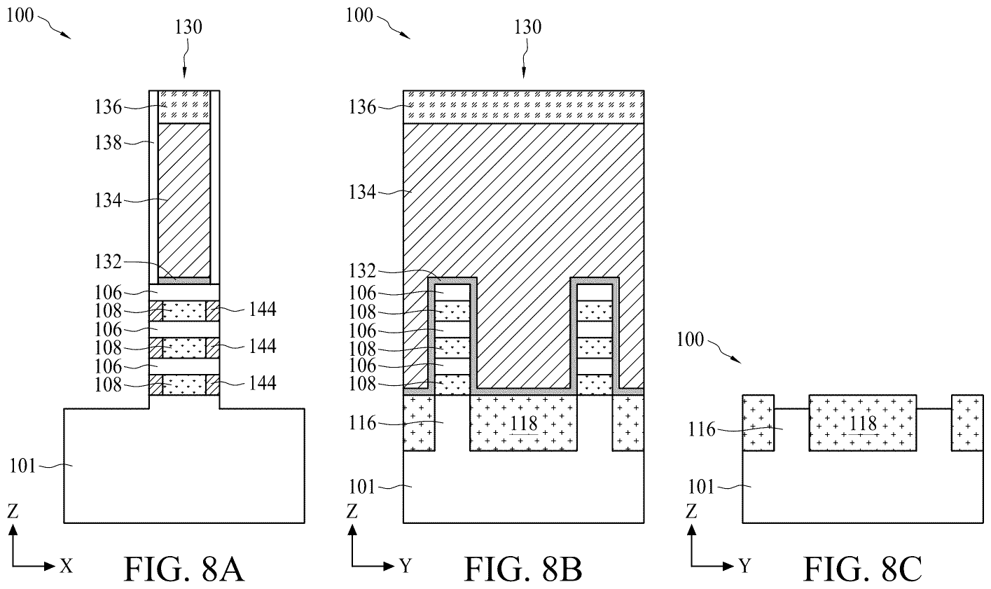

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

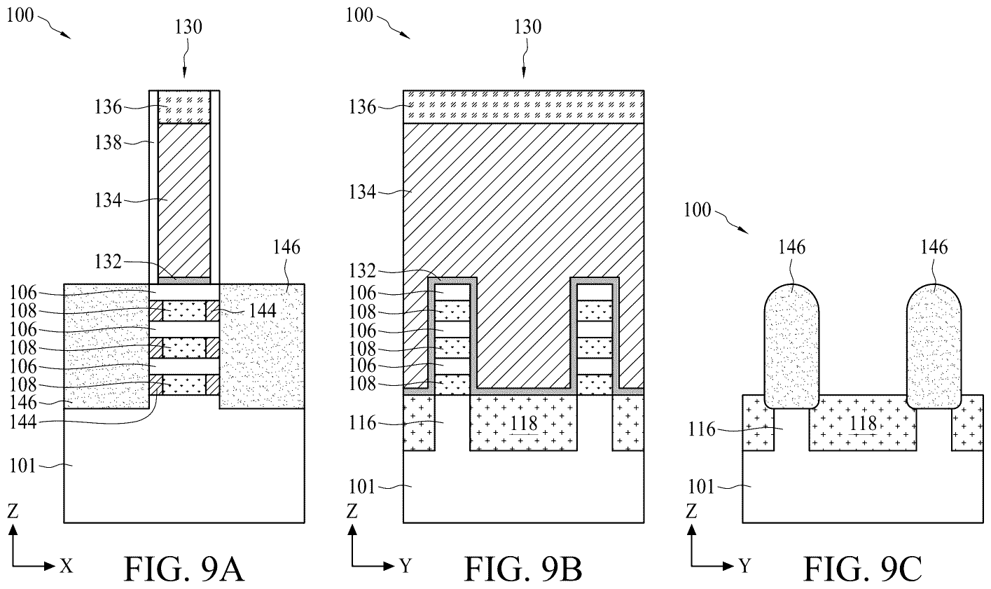

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

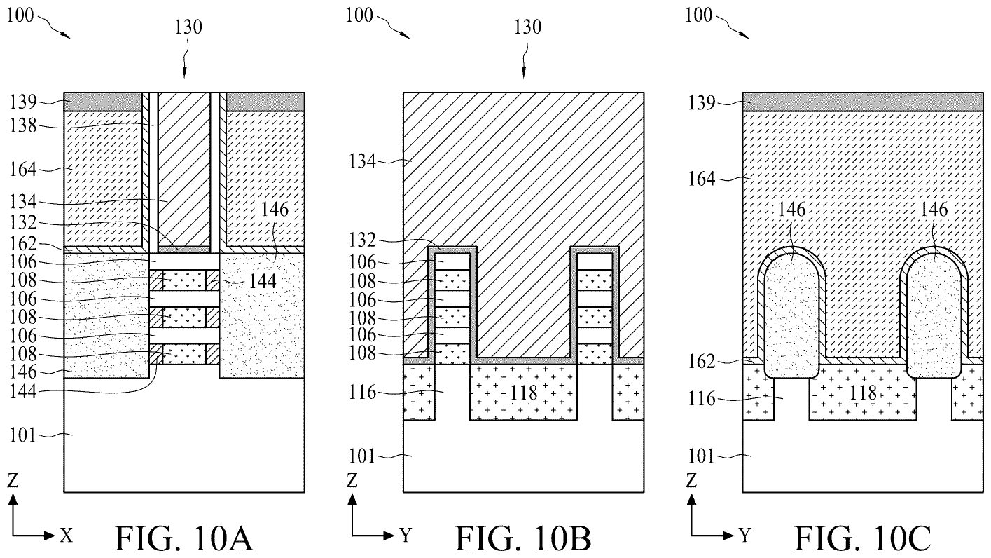

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to cure the ILD layer 164.

After the ILD layer 164 is formed, a planarization operation, such as CMP, is performed on the semiconductor device structure 100 until the sacrificial gate electrode layer 134 is exposed. In some embodiments, after the planarization process, the ILD layer 164 is recessed, and a cap layer 139 is formed on the recessed ILD layer 164. The cap layer 139 may include a nitride, such as silicon nitride, to protect the ILD layer 164 during subsequent processes. A second planarization process may be performed to remove portions of the cap layer 139 formed on the sacrificial gate electrode layer 134. After the planarization process, the top surfaces of the cap layer 139, the CESL 162, the gate spacers 138, and the sacrificial gate electrode layer 134 are substantially co-planar.

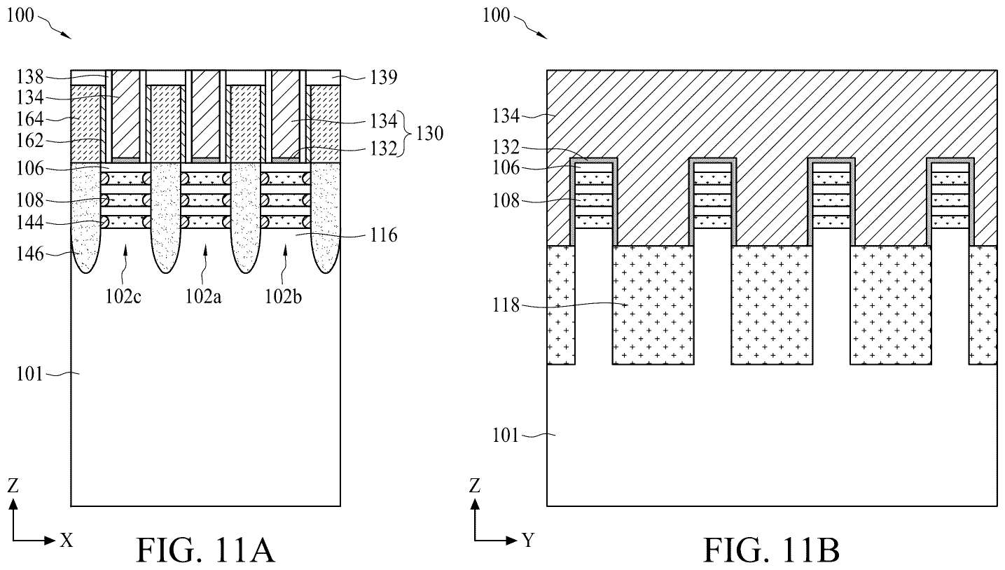

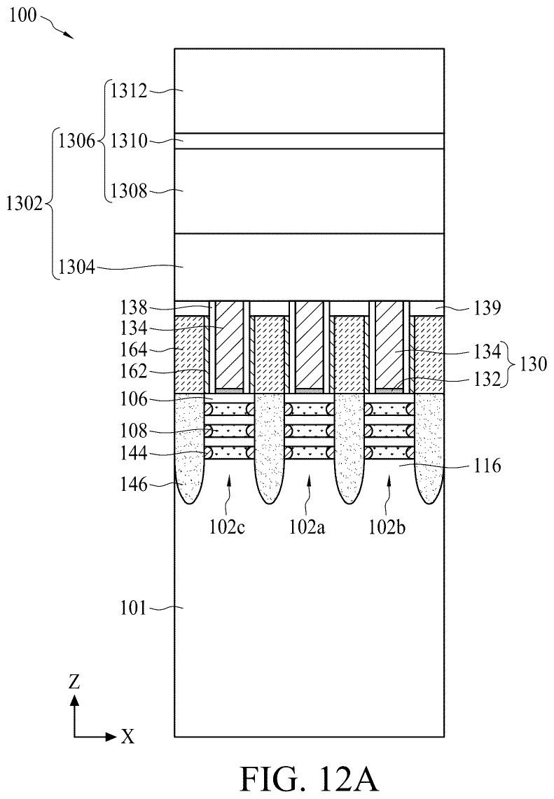

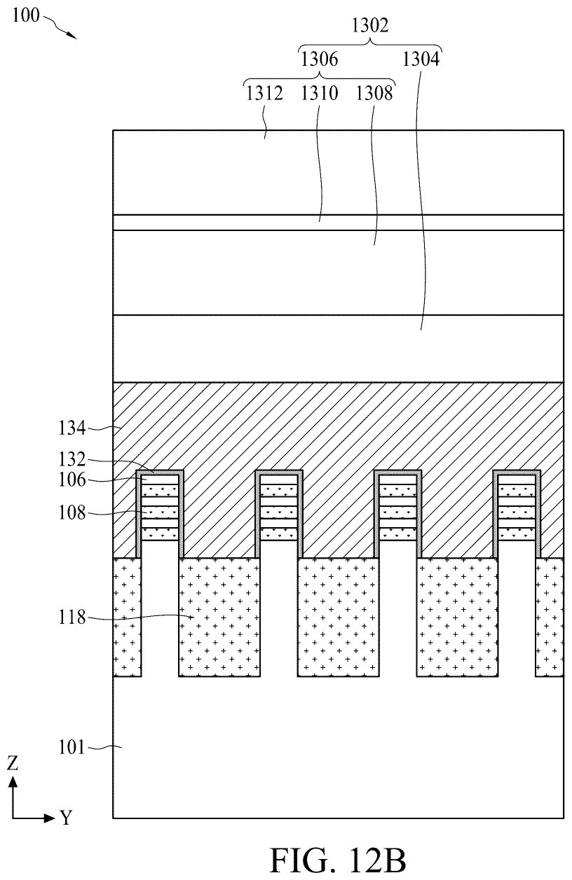

FIGS. 11A-11B to 18A-18B and 21A-21B to 25A-25B are cross-sectional side views of one of various stages of manufacturing the semiconductor device structure 100 of FIGS. 10A and 10B showing multiple fin structures disposed along the X and Y directions, respectively, in accordance with some embodiments. In FIGS. 12A and 12B, a mask structure 1302 is formed on the top surfaces of the sacrificial gate electrode layer 134, the gate spacers 138, the CESL 162, and the cap layer 139 (or the first ILD layer 164 if the cap layer 139 were not formed). The mask structure 1302 may include a hard mask 1304 and a resist layer 1306. The hard mask 1304 may be any suitable masking material. In some embodiments, the hard mask 1304 is formed of a nitrogen-containing material, such as a SiN or SiCN. The resist layer 1306 may be a single layer photoresist or a tri-layer photoresist. An exemplary tri-layer photoresist may include a bottom layer 1308, a middle layer 1310 disposed over the bottom layer 1308, and a photoresist top layer 1312 disposed over the middle layer 1310. The resist layer 1306 may be formed by any suitable process, such as a spin-on coating. The bottom layer 1308 may be a bottom anti-reflective coating (BARC) layer. The middle layer 1310 may be a silicon-containing inorganic polymer that provides anti-reflective properties and/or hard mask properties for a photolithography process. The photoresist top layer 1312 may be a DUV resist (KrF) resist, an argon fluoride (ArF) resist, an EUV resist, an electron beam (e-beam) resist, or an ion beam resist.

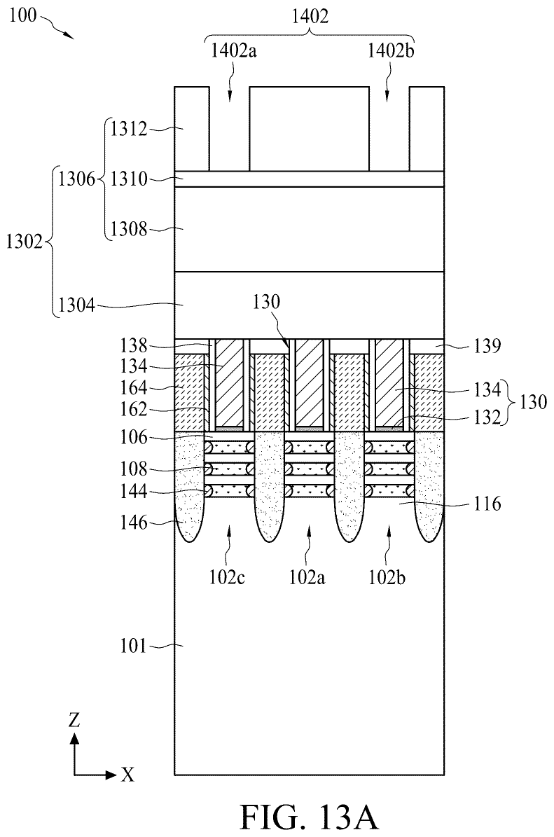

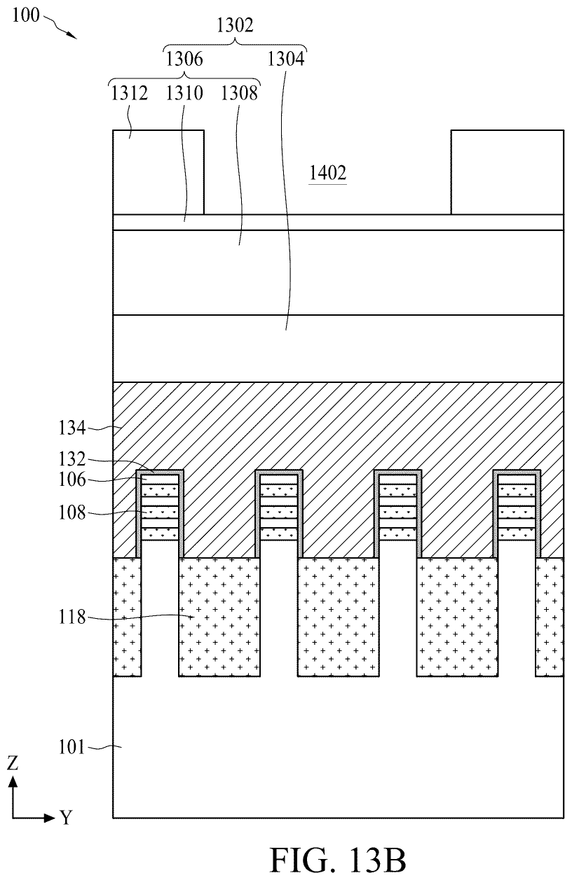

In FIGS. 13A and 13B, the photoresist top layer 1312 is patterned to form a plurality of photoresist mandrels separated from each other by an opening. For ease of illustration, only two opening 1402a, 1402b are shown. The patterned photoresist top layer 1312 is used as a mask to transfer the pattern (i.e., openings 1402a, 1402b) in the photoresist top layer 1312 into the middle layer 1310, the bottom layer 1308, and the mask layer 1304. The openings 1402a, 1402b define isolation trenches to be formed in the substrate portions of the fin structures 102b, 102c. The isolation trenches may be disposed between neighboring active regions. The term “active region” refers to a region where transistors are formed. As will be discussed in more detail below, the isolation trenches may be formed by performing a fin-cut (or sheet-cut) process. The isolation trenches are to be filled with a dielectric to form continuous poly on diffusion edge (CPODE) trenches. This fin-cut (or sheet-cut) process may be referred to a CPODE process. The term “diffusion edge” is equivalently referred to as an active edge, which is an edge abutting adjacent active regions. The CPODE process can be used to reduce gate pitch, thereby increasing the density for multi-gate devices and thus device performance required for aggressively scaled circuits and devices.

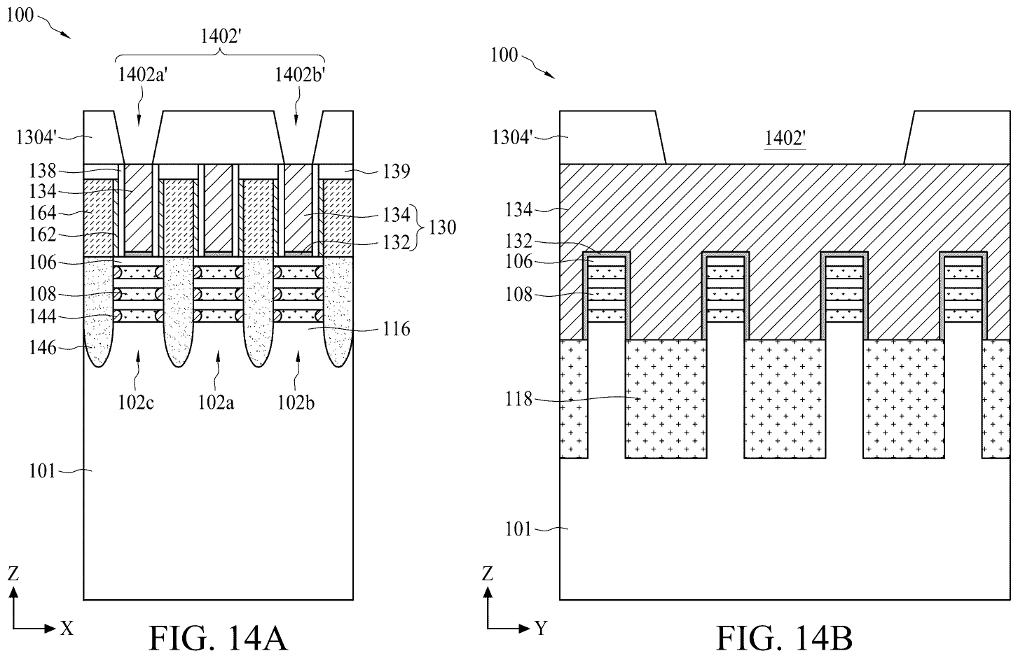

In FIGS. 14A and 14B, the patterns (i.e., openings 1402a, 1402b) in the photoresist top layer 1312 (FIGS. 13A and 13B) are transferred to the mask layer 1304 to form patterned mask layer 1304′. The bottom layer 1308, the middle layer 1310, the photoresist top layer 1312 are then removed. The formation of the patterned mask layer 1304′ may be achieved by one or more photolithographic processes. As a result of the one or more photolithographic processes, portions of the hard mask 1304 are removed, and trench patterns 1402a′, 1402b′ (collectively referred to as trench pattern 1402′) are formed in the patterned mask layer 1304′, and a portion of the sacrificial gate electrode layer 134 is exposed. The trench patterns 1402a′, 1402b′ are elongated openings in alignment with the sacrificial gate structures 130. The removal of portions of the hard mask 1304 (and native oxide formed thereon) may be performed using an etch chemistry, such as CF₄, CHF₃, CH₂F₂, CHF₃, C₄F₆, or the like. The patterned mask layer 1304′ may then be used to protect active regions during subsequent removal of the exposed sacrificial gate structures and fin-cut (or sheet-cut) process.

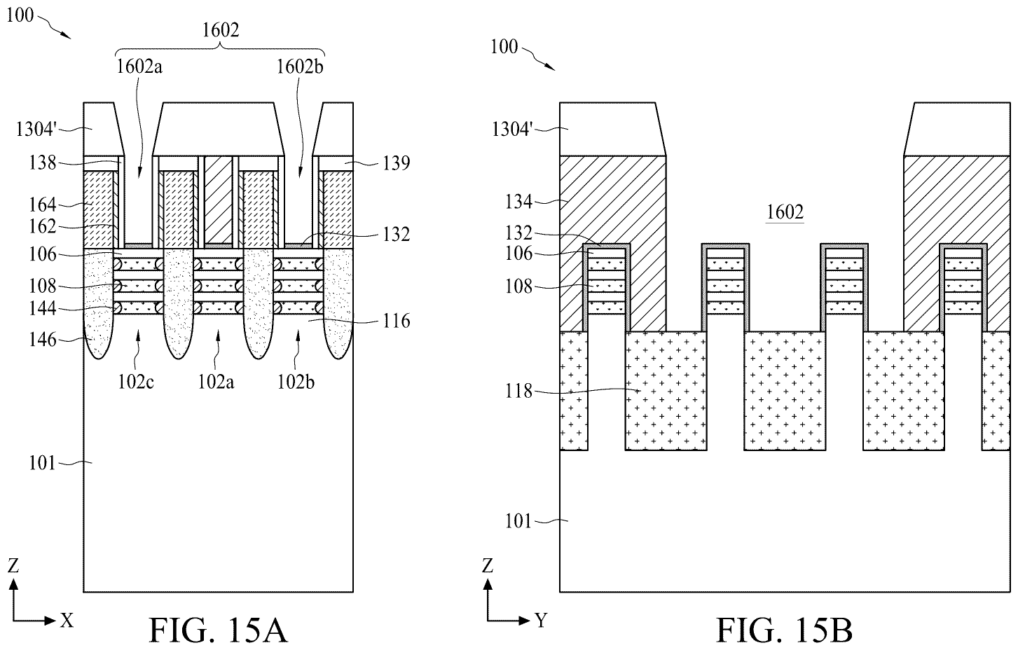

In FIGS. 15A and 15B, the exposed sacrificial gate structures (e.g., sacrificial gate electrode layer 134) are selectively removed to form openings 1602a, 1602b (collectively referred to as openings 1602). The openings 1602 expose the gate spacers 138 and the sacrificial gate dielectric layer 132. The removal of the exposed sacrificial gate structures may be performed by a selective etch process that removes the sacrificial gate electrode layer 134 but does not substantially affect the gate spacers 138 and the sacrificial gate dielectric layer 132. The sacrificial gate dielectric layer 132 protects the first and second semiconductor layers 106, 108 during the etch back process. In some embodiments, the sacrificial gate dielectric layer 132 may also be removed during the selective etch process. In some embodiments, an etch chemistry that is selective to the sacrificial gate structures to be etched, while minimizing etching of the surrounding dielectric layers, such as the insulating material 118, the gate spacers 138, the CESL 162, and the first ILD layer 164. In some embodiments, the sacrificial gate structures 130 may be removed using chlorine containing gases, such as SiCl₄, BCl, Cl₂, CHCl₃, CCl₄, and/or BCl, bromine-containing gas, such as HBr and/or CHBr₃, iodine-containing gas, other suitable gases and/or plasmas, and/or combinations thereof. In some embodiments, the sacrificial gate electrode layer, 134, has a top that is flush with the top of the sacrificial gate dielectric layer 132. The following fin-cut or sheet-cut process will remove the sacrificial gate electrode layer 134 and the sacrificial gate dielectric layer 132 in the CPODE trench.

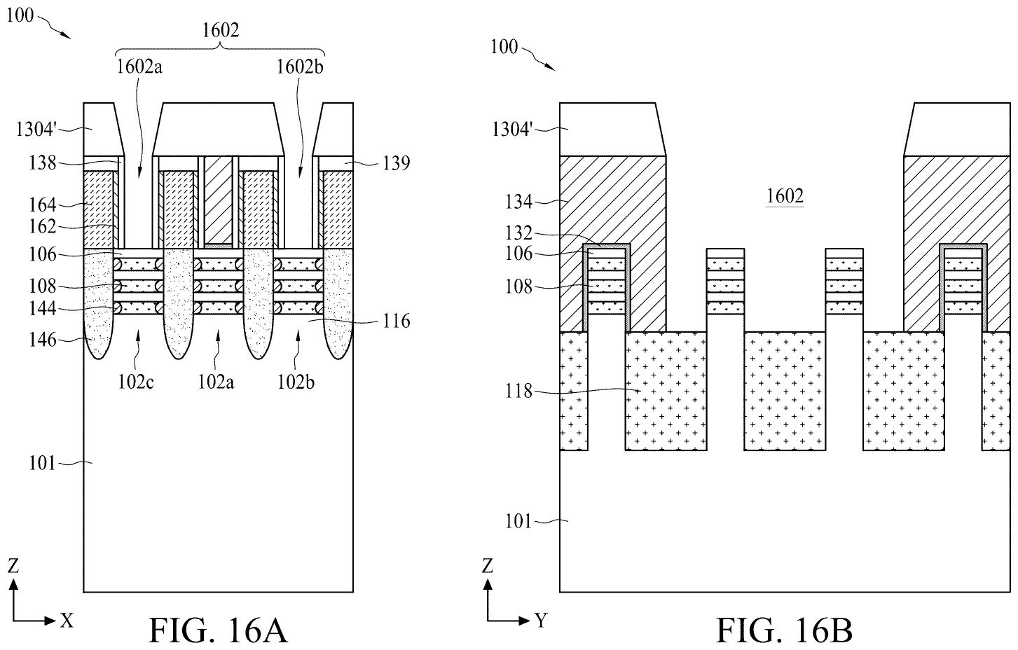

In FIGS. 16A and 16B, an etch process is performed to remove the sacrificial gate dielectric layer 132. The etch process may be a dry etch, a wet etch, or a combination thereof. The etch process selectively removes the sacrificial gate dielectric layer 132 without affecting the first and second semiconductor layers 106, 108, as well as the sacrificial gate electrode layer 134.

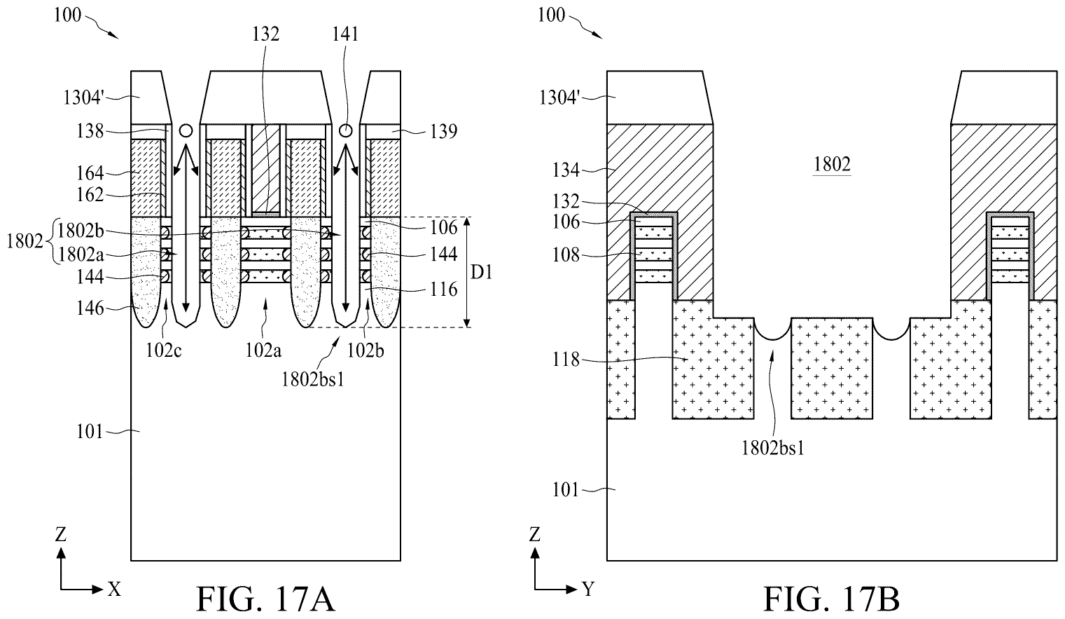

FIGS. 17A and 17B to 24A and 24B illustrate processes of extending the openings 1602 into substrate portions of fin structures 102b, 102c for forming isolation trenches. Particularly, the isolation trenches (and thus subsequent CPODE structures) are formed such that the exposed substrate 101 has a substantially flat top surface, which prevents the top of the exposed substrate from forming fin-like structures and becoming parasitic bipolar junction transistors (BJTs). In FIGS. 17A and 17B, a first semiconductor etch process 141 is performed to remove the first and second semiconductor layers 106, 108 (and in some cases, a small portion of the exposed insulating material 118 due to bombardment of ions), thereby forming a first section of the isolation trenches 1802. The first semiconductor etch process 141 is a fin-cut (or sheet-cut) process. The first semiconductor etch process 141 is performed using the patterned mask layer 1304′ as an etching mask. The first semiconductor etch process 141 may be dry etch, reactive ion etch (RIE), and/or other suitable processes. In some embodiments, the first semiconductor etch process 141 is an anisotropic etch (directional etch) process. The first semiconductor etch process 141 is performed so that the exposed first semiconductor layers 106, the second semiconductor layers 108, and portions of the substrate 101 forming the fin structures 102b, 102c are selectively removed. A portion of the insulating material 118 around the fin structures 102b, 102c may also be removed. In some embodiments, the removal of the exposed first semiconductor layers 106, the second semiconductor layers 108, and portions of the substrate 101 is achieved using a self-aligned CPODE etch process. The self-aligned CPODE etch process is configured to have high etch selectivity so that the etch rate of the first and second semiconductor layers 106, 108 is greater than the etch rate of the inner spacers 144. As a result, the inner spacers 144 remain substantially intact after the fin-cut process.

As a result of the first semiconductor etch process 141, isolation trenches 1802a, 1802b (collectively referred to as isolation trenches 1802) are formed and extended into portions of the substrate 101 forming the fin structures 102b, 102c (FIG. 17A). In various embodiments, the first semiconductor etch process 141 is performed such that the first section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. In some embodiments, the isolation trenches 1802a, 1802b may have a first depth D1, which is defined by a distance between the topmost first semiconductor layer 106 and a bottom surface 1802bs1 of the isolation trenches 1802a, 1802b. The first depth D1 may be selected according to desirable level of the narrowest critical dimension (CD). In some embodiments, the bottom surface 1802bs1 of the isolation trenches 1802a, 1802b is at substantially the same elevation as the bottom of the epitaxial S/D features 146. In some embodiments, the bottom surface 1802bs1 of the isolation trenches 1802a, 1802b is below a top surface of the well portion of the substrate 101. In some embodiments, the first depth D1 is substantially equal to the height of the epitaxial S/D features.

The self-aligned CPODE etch process can be achieved by a plasma etch using a bromine-based etch chemistry (and/or a chlorine-based etch chemistry) and an oxygen-based chemistry. Exemplary bromine-based etch chemistry may include, but are not limited to, HBr, Br₂, BBr₃, or the like, or a combination thereof. Exemplary chlorine-based etch chemistry may include, but are not limited to, Cl₂, CHCl₃, CCl₄, BCl₃, or the like, or a combination thereof. Exemplary oxygen-based etch chemistry may include, but are not limited to, O₂, CO₂, O₃, water vapor, or the like, or a combination thereof. In some embodiments, the plasma etch is a high density plasma process chamber using an ICP (inductive coupled plasma) or dipole antenna plasma source. In some embodiments, resonant antenna plasma source or electron cyclotron resonance (ECR) plasma source may also be used to enable low pressure operation (e.g., about 0.2±0.05 mTorr). The plasma may be driven by an RF power generator using an AC electrical current operating on a frequency of multiple of 13.56 MHz. The process chamber may be operated at a pressure in a range of about 0.2 mTorr to about 150 mTorr and a temperature of about 20 degrees Celsius to about 120 degrees Celsius. The RF power generator is operated to provide source power between about 100 W to about 2500 W. Higher directionality can be achieved by adding a bias power to a substrate pedestal in the process chamber. In such cases, a DC bias power operating in a range of about 0 V to about 1000 V (e.g., about 50V-150 V) may be used. In some cases, a pulse plasma etch may be used. In such cases, the output of the power generator may be controlled by a pulse signal having a duty cycle in a range of about 5% to 95%. Alternatively, the self-aligned CPODE etch process may use a bias power only (with zero source power) to enhance etch directionality.

While a bromine-based or a chlorine-based etch chemistry is discussed, other etch chemistry, such as a fluorine-based etch chemistry, may also be used. Exemplary fluorine-containing gas may include, but is not limited to, CF₄, SF₆, CH₂F₂, C₂H₄F₂, CHF₃, C₂F₆, NF₃, or the like, or a combination thereof. Alternatively, the etchant used in the first semiconductor etch process 141 may be, a fluorine/chlorine-based etch chemistry, a fluorine/bromine-based etch chemistry, or any combination thereof.

In some embodiments, the plasma etch may be performed in a plasma etch chamber with in-situ ALD capability forming silicon oxide or silicon nitride.

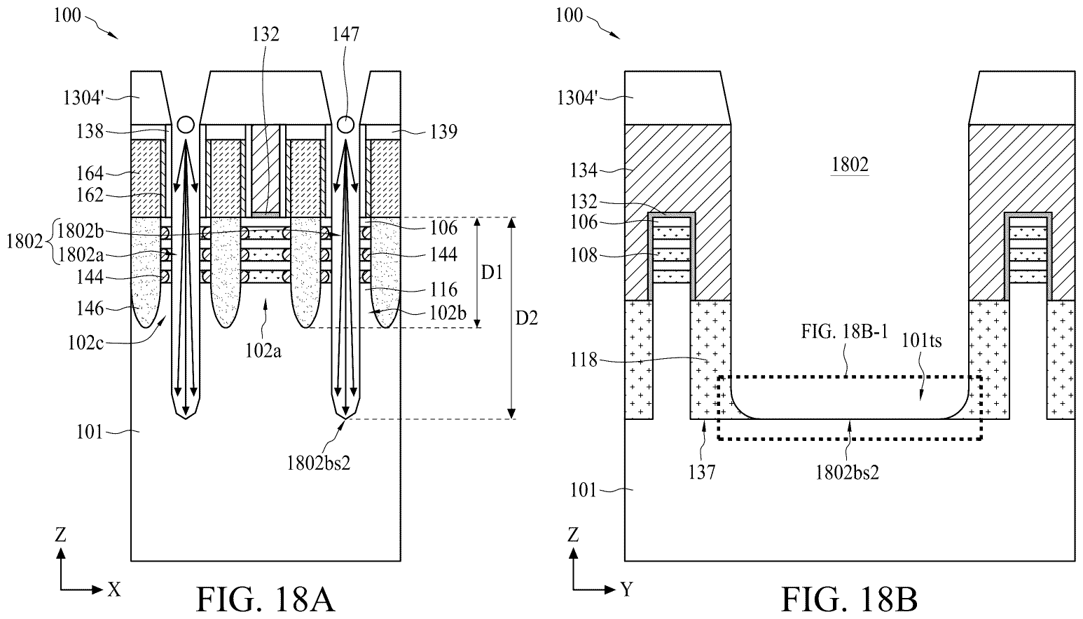

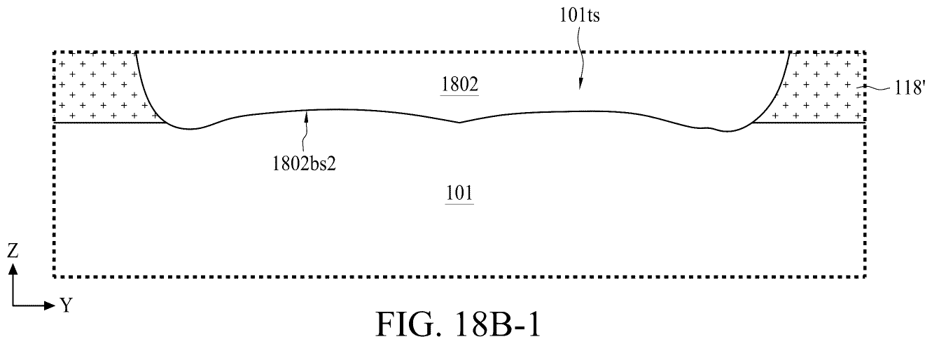

In FIGS. 18A and 18B, a second semiconductor etch process 147 is performed to further remove the exposed insulating material 118 and the substrate portion forming the fin structure 102b, 102c. Likewise, the second semiconductor etch process 147 is performed such that a second section of the isolation trenches 1802a, 1802b are formed with a straight and symmetric sidewall profile with respect to an imaginary line passing through a center of the respective isolation trenches 1802a, 1802b in the depth direction of the isolation trenches 1802a, 1802b. The isolation trenches 1802 are formed with a uniform CD along the depth direction. Particularly, the second semiconductor etch process 147 is performed such that the bottom of the isolation trench 1802, or stated differently, a top surface 101ts of the exposed substrate 101, is flat or substantially flat. The term “flat” or “substantially flat” described in this disclosure refers to a surface that is substantially planner having a standard deviation from a flat surface of less than about 5 nm to about 20 nm over the surface. The substrate 101 with a flat top surface 101ts does not form a parasitic bipolar junction transistor as would otherwise create in a conventional etch semiconductor process where the substrate 101 is etched to form high-aspect ratio fin structures in the well region, leading to formation of EPI-substrate-EPI leakage path.

The second semiconductor etch process 147 is performed using an etch chemistry similar to the first semiconductor etch process 141. The substrate portion of the fin structure 101b, 102c may be removed by the second semiconductor etch process 147 using a plasma etch process comprising HBr and/or Cl₂. In some embodiments, O₂ and/or CO₂ may be added to HBr and/or Cl₂ based plasma to facilitate dissociation of the plasma by product. In some embodiments, the plasma etch process may be a high density plasma process using process conditions similar to the first semiconductor etch process 141. The second semiconductor etch process 147 is performed to extend the isolation trenches 1802a, 1802b to an elevation substantially equal to an interface 137 defined by the substrate 101 and the insulating material 118. The isolation trenches 1802a, 1802b have a second depth D2 measuring from the topmost first semiconductor layer 106 to a bottom surface 1802bs2 of the isolation trenches 1802a, 1802b. In other words, the depth of each isolation trench 1802a, 1802b is extended from the first depth D1 to the second depth D2. The isolation trenches 1802 with homogeneous CD along the depth direction can be obtained through a cyclic process. For example, the processes in FIGS. 17A and 17B to 18A and 18B may repeat until the isolation trenches 1802a, 1802b reach a predetermined height.

One or more etch conditions may be controlled to achieve low selectivity etch between silicon (e.g., substrate 101) and silicon oxide (e.g., insulating material 118). For example, a low-pressure process (e.g., chamber pressure below about 50 mTorr) and/or high bias power to the substrate pedestal (e.g., greater than 300 V) may be utilized during the second semiconductor etch process 147 to compensate for etch selectivity needed for removing the insulating material 118 and the substrate portion of the fin structures 102b, 102c. In some embodiments, the bias power used during the second semiconductor etch process 147 is greater than that of the first semiconductor etch process 141.

In some embodiments, boron trichloride (BCl₃), or the like, may be used to enhance the etch selectivity of silicon oxide, achieving low selective etch between silicon and silicon oxide. In some embodiments, the bottom surface 1802bs2 of the isolation trenches 1802a, 1802b may be at an elevation within a well region or an accumulation region of the substrate 101. The term “accumulation region” refers to a non-conductive region in the substrate 101, which is below a depletion region (a conductive region located at/near the well region of the substrate 101). In any case, the second depth D2 is sufficient to block the path of leakage current through epitaxial source/drain features and the silicon substrate. In some embodiments, the second depth D2 may be in a range between about 60 nm and about 200 nm.

In some embodiments, the top surface 101ts of the exposed substrate 101 may have a wavy profile after the second semiconductor etch process 147. FIG. 18B-1 illustrates an enlarged view of a portion of the substrate 101 shown in FIG. 18B, in accordance with some embodiments. It is understood that the embodiment of FIG. 18B-1 is applicable to the embodiment of FIG. 18B and any one or more embodiments shown in this disclosure where the bottom of the isolation trenches 1802 is at an elevation of the interface 137 defined by the substrate 101 and the insulating material 118. The subsequent CPODE structures thus have a bottom with a wavy profile.

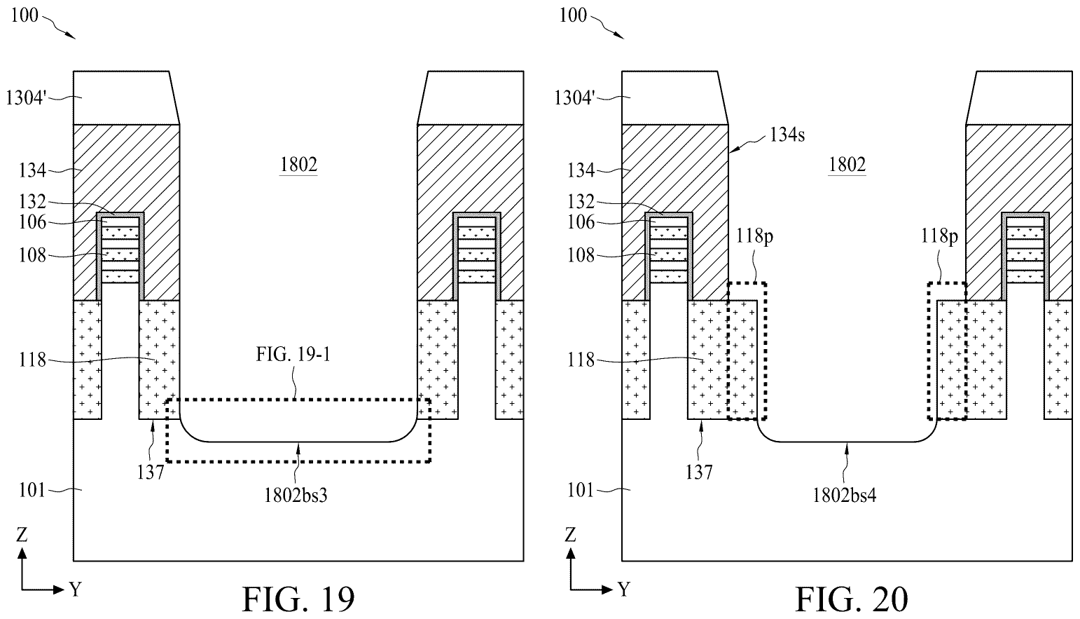

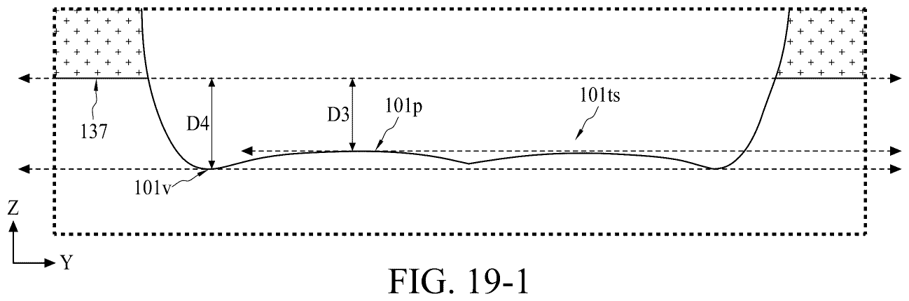

In some embodiments, the second semiconductor etch process 147 is performed such that the bottom surface of the isolation trenches 1802 is at an elevation below the interface 137 defined by the substrate 101 and the insulating material 118. In some cases, the bottom surface is at an elevation within the well region of the substrate 101. FIG. 19 illustrates an embodiment where the isolation trenches 1802 are etched to have a bottom 1802bs3 extending a depth into the well region of the substrate 101. Such recess of the substrate 101 may be obtained by controlling one or more etch conditions to achieve low selectivity etch between silicon (e.g., substrate 101) and silicon oxide (e.g., insulating material 118). For example, a low-pressure process (e.g., chamber pressure below about 50 mTorr) and/or high bias power to the substrate pedestal (e.g., greater than 300 V) may be utilized during the second semiconductor etch process 147 to compensate for etch selectivity needed for removing the insulating material 118 and the substrate portion of the fin structures 102b, 102c. In some embodiments, the bias power used during the second semiconductor etch process 147 is greater than that of the first semiconductor etch process 141.

In some embodiments, the second semiconductor etch process 147 is performed such that a portion of the insulating material 118 remains and protrudes inwardly over a sidewall 134s of the sacrificial gate electrode layer 134, as shown in FIG. 20. Such protrusion 118p of the insulating material 118 may be formed from the protection of the patterned mask layer 1304′ during the second semiconductor etch process 147. Likewise, the isolation trenches 1802 are etched to have a bottom extending a depth into the well region of the substrate 101. Therefore, the bottom surface 1802bs4 is at an elevation below the interface 137 defined by the substrate 101 and the insulating material 118.

In either embodiment of FIG. 19 or FIG. 20, the top surface 101ts of the substrate 101 may have a wavy profile. FIG. 19-1 illustrates an enlarged view of a portion of the substrate 101 shown in FIG. 19, in accordance with some embodiments. In some embodiments, the exposed substrate 101 is etched to have a peak 101p and a valley 101v. The peak 101p may have a distance D3 measuring from the highest point at the top surface 101ts of the exposed substrate 101 to the interface 137 (defined by the substrate 101 and the insulating material 118), and the valley 101v may have a distance D4 measuring from the lowest point at the top surface 101ts of the exposed substrate 101 to the interface 137. In some embodiments, the distance D3 and the distance D4 may have a ratio of about 1.1 to about 1.5, such as about 1.3. It is understood that the embodiment of FIG. 19-1 is applicable to the embodiment of FIG. 20 and/or any one or more embodiments in this disclosure where the bottom of the isolation trenches 1802 is at an elevation within the well region of the substrate 101 (i.e., below the interface 137). The subsequent CPODE structures thus have a bottom with a wavy profile.

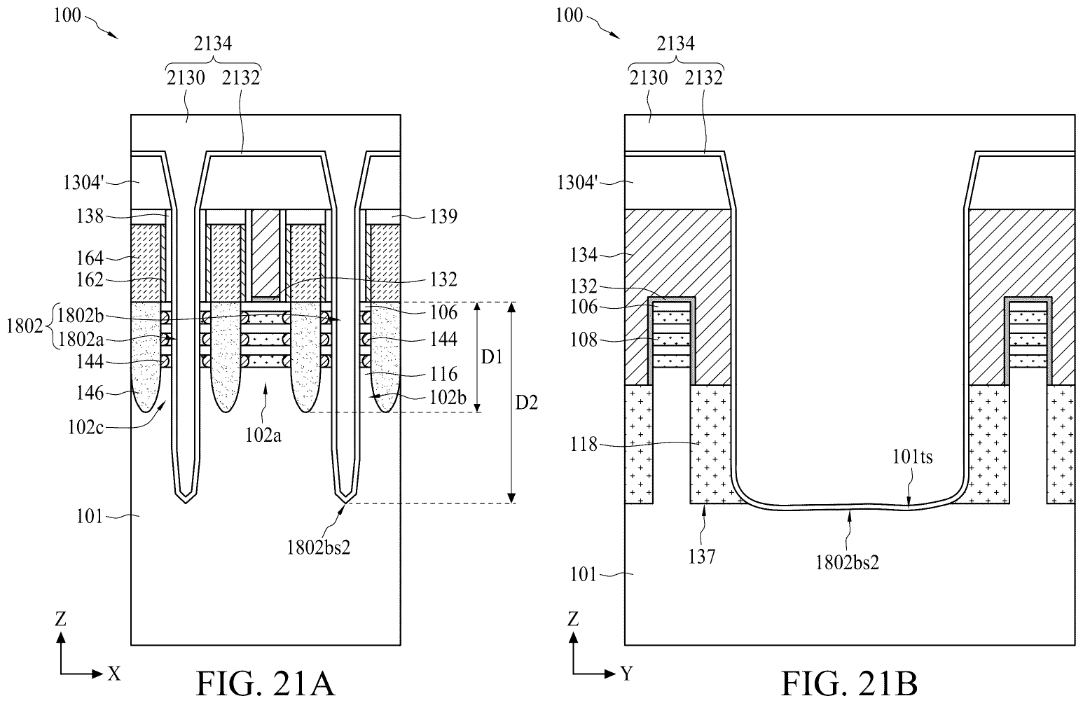

In FIGS. 21A and 21B, the isolation trenches 1802 (FIGS. 18A and 18B) are filled with a dielectric material 2130. In some embodiments, a dielectric liner 2132 may be disposed between the dielectric material 2130 and the exposed surfaces of the isolation trenches 1802. The dielectric material 2130 and the dielectric liner 2132 filled within the isolation trenches 1802 form isolation trench structures (so-called CPODE trenches) 2134. The isolation trench structures 2134 have a substantially flat bottom surface 1802bs2. The bottom surface 1802bs2 of the isolation trench structure 2134 and the top surface 101ts of the substrate 101 define an interface that is substantially flat. The dielectric material 2130 and the dielectric liner 2132 may be made of an oxygen-containing material, such as silicon oxide (SiO₂); a nitrogen-containing material, such as silicon nitride, silicon oxynitride (SiON), SiOCN, SiCN; a low-K dielectric material; or any suitable dielectric material. The dielectric material 2130 may include a material chemically different than the and the dielectric liner 2132, and may be formed by any suitable process, such as a CVD, PECVD, FCVD, or ALD process.

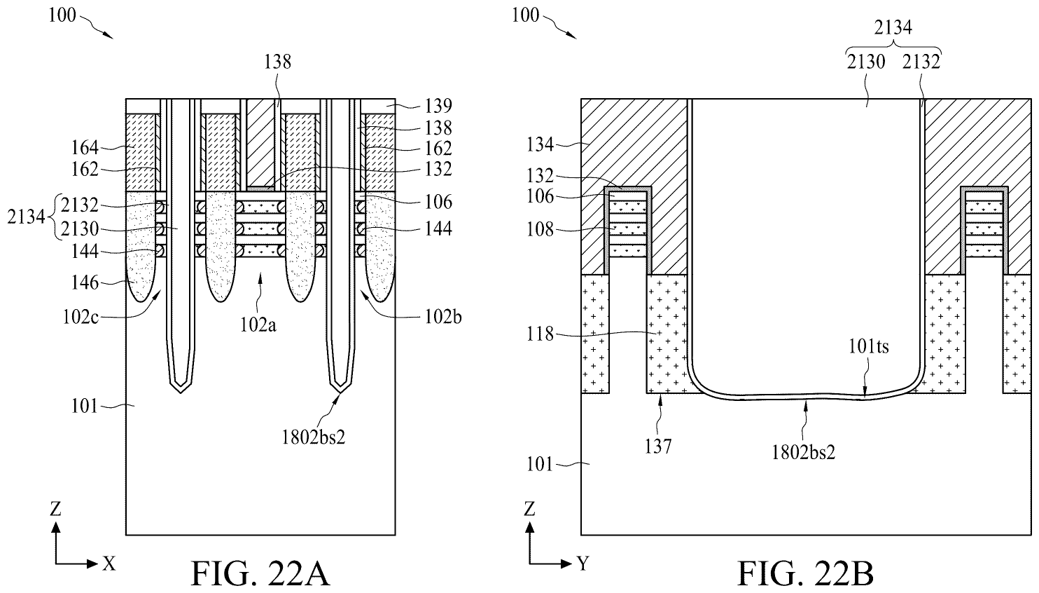

In FIGS. 22A and 22B, once the isolation trenches 1802 are filled, a planarization process, such as a CMP process, may be performed to remove portions of the dielectric material formed over the patterned mask layer 1304′. The planarization process may be performed until a portion of the cap layer 139 or the ILD layer 164 is exposed.

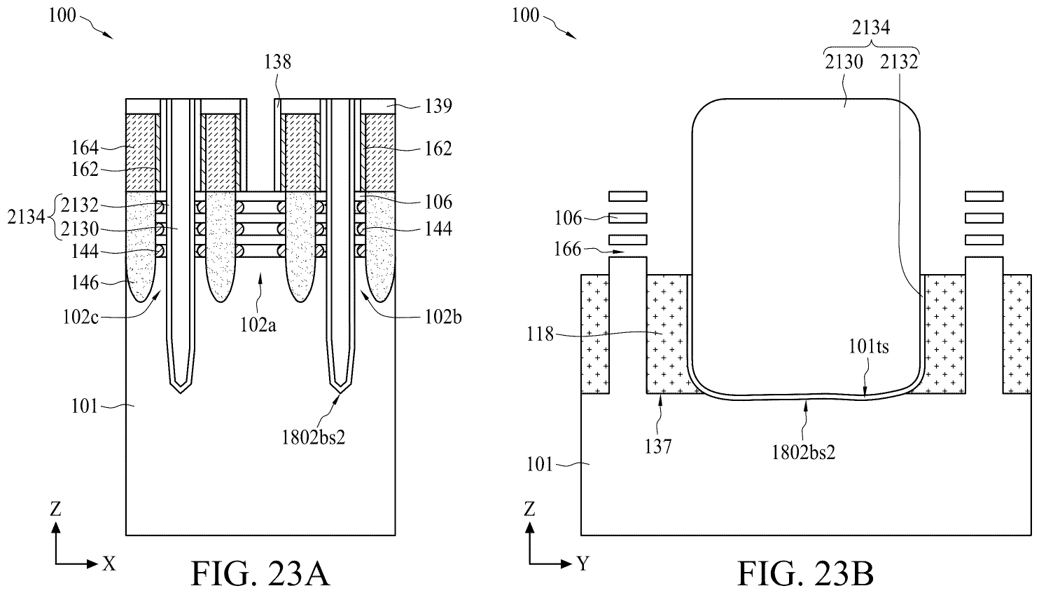

In FIGS. 23A and 23B, the sacrificial gate structures 130, the sacrificial gate dielectric layer 132, and the second semiconductor layers 108 are removed. The exposed dielectric liner 2132 on the sidewalls of the dielectric material 2130 may also be removed. The removal of the sacrificial gate structures 130 and the semiconductor layers 108 forms an opening 166 between the first semiconductor layers 106. The cap layer 139, the CESL 162, and the first ILD layer 164 protect the epitaxial source/drain features 146 during the removal processes. The sacrificial gate structures 130 can be removed using plasma dry etching and/or wet etching. In some embodiments, a wet etchant such as a tetramethylammonium hydroxide (TMAH) solution can be used to selectively remove the sacrificial gate electrode layer 134 and the sacrificial gate dielectric layer 132 but not the gate spacers 138, the isolation trench structures 2134, the first ILD layer 164, and the CESL 162. After the removal of the sacrificial gate structures 130, the first semiconductor layers 106 and the inner spacers 144 are exposed to the opening 166.

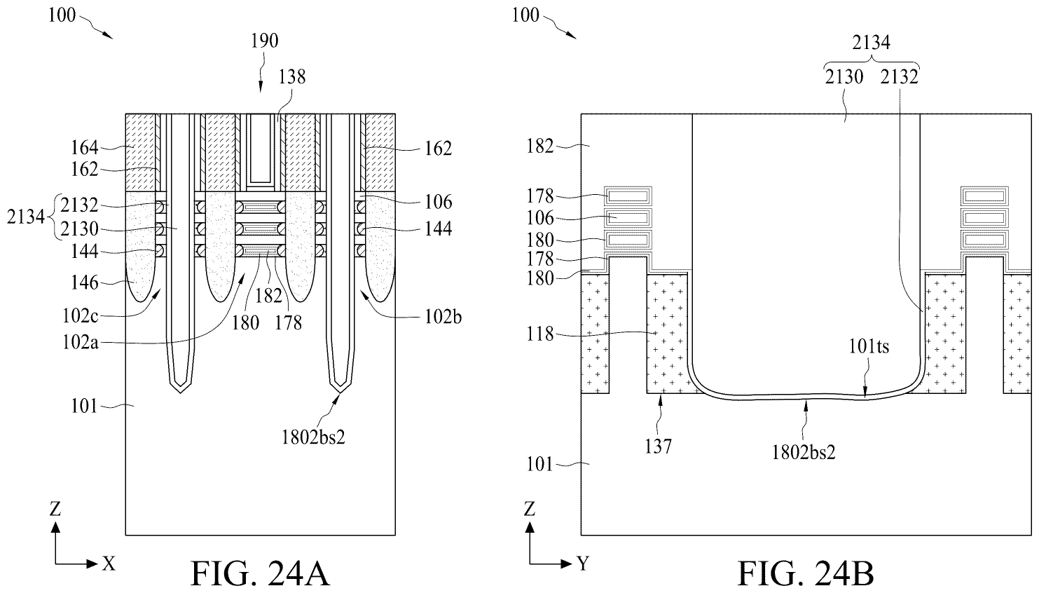

In FIGS. 24A and 24B, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101, the insulating material 118, and the dielectric layer 2132. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, the CESL 162, and the cap layer 139). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL (if any) and the gate dielectric layer 180, the gate electrode layer 182 is formed on the gate dielectric layer 180. The gate electrode layer 182 filles the openings 166 (FIG. 23A) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAIN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, the cap layer 139 (if any), and the gate spacers 138 may be removed by a planarization process, such as by a CMP process. After the CMP process, the top surfaces of the isolation trench structure 2134, the first ILD layer 164, the CESL 162, the gate spacers 138, and the gate electrode layer 182 are substantially co-planar.

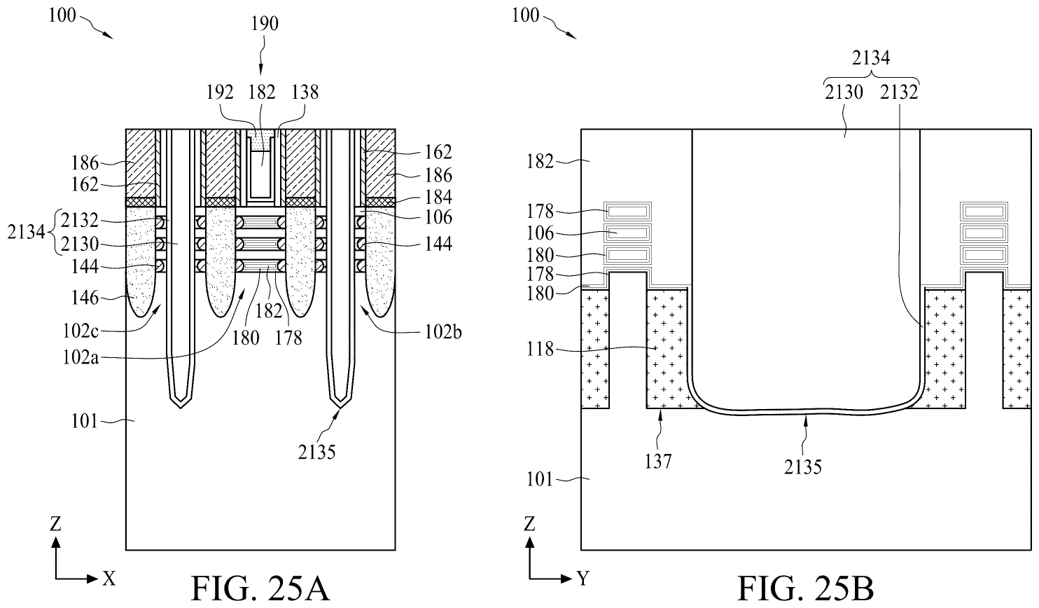

In FIGS. 25A and 25B, the gate electrode layer 182 may optionally be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 192 is formed over the gate electrode layer 182. The self-aligned contact layer 192 may be a dielectric material (e.g., SiN) having an etch selectivity relative to the ILD layer 164. The self-aligned contact layer 192 protects the gate electrode layer 182 during formation of the contact openings. A silicide layer 184 is then formed on the epitaxial source/drain features 146, and a S/D contact 186 is formed in the contact opening on the silicide layer 184. The contact 186 may include an electrically conductive material, such as Ru, Mo, Co, Ni. W, Ti, Ta, Cu, Al, TiN, or TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

As can be seen, the isolation trench structure 2134 has a substantially flat bottom surface 1802bs2 that is at the same elevation as the interface 137 defined by the substrate 101 and the insulating material 118. The bottom surface 1802bs2 extends across the diameter of the isolation trench structure 2134 and is in contact with a substantially flat top surface of the substrate 101. It has been observed that lattice mismatch and different thermal expansion properties between the substrate 101 and the dielectric material 2130 (of the isolation trench structure 2134) can lead to charge trapping in the interface of silicon and refill dielectric heterostructures. Negative trapped charges in the interface of silicon and refill dielectric heterostructures may lead to P-type EPI to P-type EPI leakage through parasitic PNP bipolar junction transistor (BJT), while positive trapped charges in the interface of silicon and refill dielectric heterostructures may lead to N-type EPI to N-type EPI leakage through parasitic NPN BJT. While it is possible to reduce the depth of CPODE/CMODE structures to prevent formation of parasitic fin-like BJT below the STI (i.e., insulating material 118), insufficient etch amount can still lead to residues of silicon on the sidewall of the STI, resulting in current leakage. By forming the isolation trench structure 2134 with a flat bottom surface 1802bs2, the top of the substrate 101 does not form fin-like structures which would otherwise become parasitic BJTs. As a result, the leakage current through epitaxial source/drain features and silicon substrates is avoided.

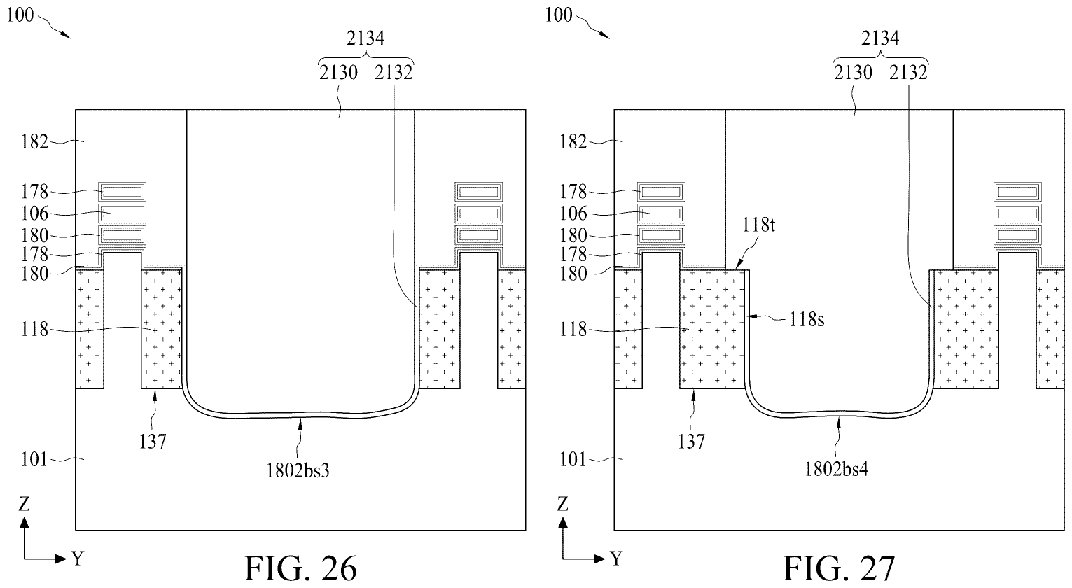

FIGS. 26 and 27 illustrate cross-sectional views of the semiconductor device structure 100, in accordance with the embodiments shown in FIGS. 19 and 20, respectively. As can be seen, the isolation trench structures 2134 are formed such that the bottom of the isolation trench structures 2134 extends a depth into the well region of the substrate 101. Particularly, the bottom surface 1802bs3 of the isolation trench structure 2134 and the bottom surface 1802bs4 of the isolation trench structure 2134 are at an elevation below the interface 137 defined by the substrate 101 and the insulating material 118. In either case, the isolation trench structures 2134 have a sidewall consisting of the insulating material 118 and the substrate 101. In the embodiment of FIG. 27, a portion of the insulating material 118 protruding into the isolation trench structure 2134 has a top surface 118t in contact with the dielectric material 2130, and a sidewall 118s of the insulating material 118 is in contact with the dielectric liner 2132.

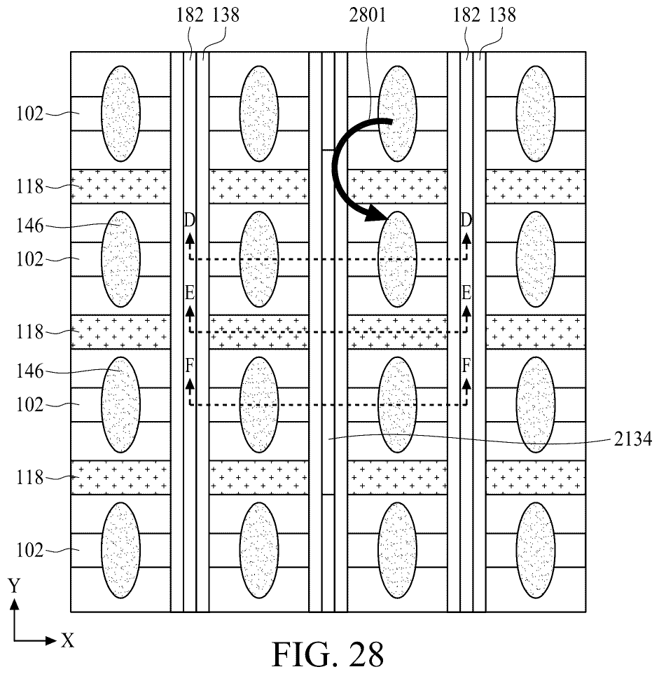

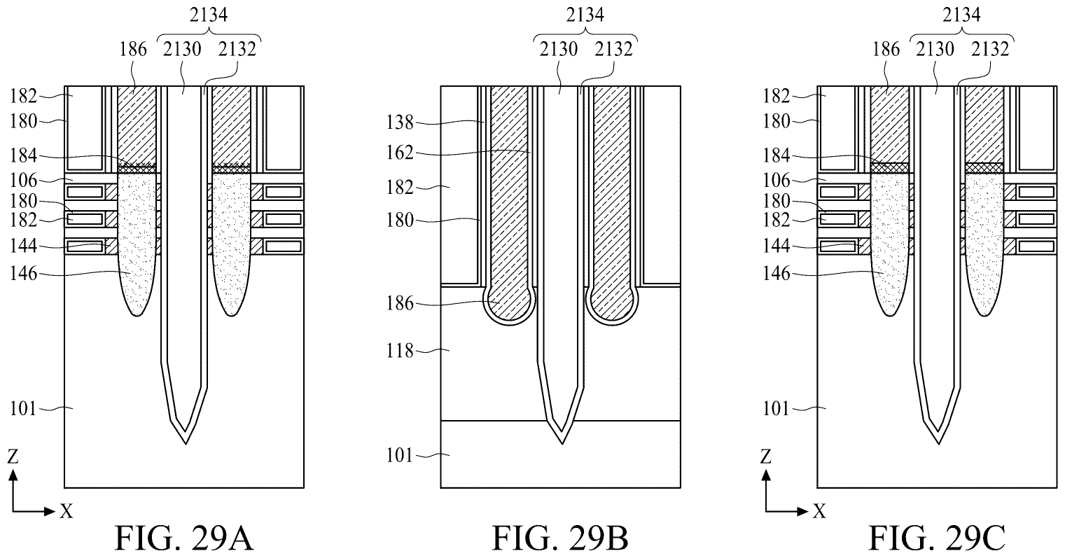

FIG. 28 is a top view of the semiconductor device structure 100 shown in FIGS. 25A and 25B, in accordance with some embodiments. Some components of the semiconductor device structure 100, such as the self-aligned contact layer 192, and the CESL 162, etc., are omitted in FIG. 28 for clarity. FIGS. 29A, 29B, 29C are cross-sectional views of the semiconductor device structure 100 taken along line D-D, line E-E, and line F-F of FIG. 28, respectively. As can be seen in FIG. 29B, the isolation trench structure 2134 extends through the insulating material 118 (e.g., STI) and into the well region of the substrate 101 to block leakage current between transistors. In addition, the isolation trench structure 2134 with a flat silicon interface also eliminates the parasitic fin BJT in and/or below the well region of the substrate 101. Therefore, the leakage path 2801 (FIG. 28) through EPI-transistors-substrate-EPI is avoided.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

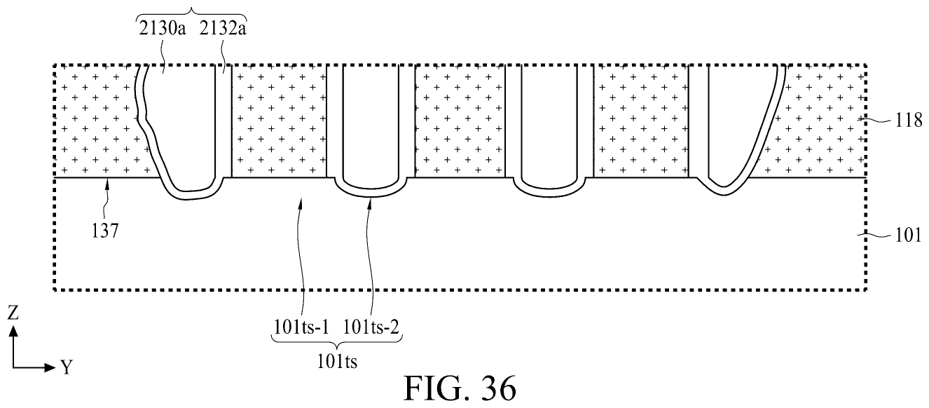

FIGS. 30-36 illustrate an alternative embodiment where a portion of insulating material 118 remains within the isolation trench structure and on the top surface 101ts of the exposed substrate 101. In FIG. 30, after the first semiconductor etch process 141 removes the first and second semiconductor layers 106, 108 (and a small portion of the insulating material 118 in some cases), a modified second semiconductor etch process 149 is performed to further remove portions of the exposed insulating material 118 and the substrate portion forming the fin structures 102b, 102c. The modified second semiconductor etch process 149 is a selective etch process that selectively or preferentially removes silicon (e.g., substrate portion forming the fin structures 102b, 102c) over silicon oxide (e.g., insulating material 118). As a result, the insulating material 118 in the form of a plurality of fin-like structures 118f remains at the bottom of the isolation trenches 1802a, 1802b (collectively referred to as isolation trenches 1802). The top of the fin-like structures 118f of the insulating material 118 is at an elevation below the top surface of the insulating material 118, or an interface 142 defined by the insulating material 118 and the sacrificial gate electrode layer 134. In some embodiments, the top surface 101ts of the exposed substrate 101 may have a flat and curved profile (FIG. 36) after the modified second semiconductor etch process 149.

Directional silicon etch can be achieved through a plasma etch process using HBr/Cl₂ based chemistry with addition of O₂ and/or CO₂, similar to those used in the second semiconductor etch process 147. Higher directionality can be achieved by adding a bias power to a substrate pedestal in the process chamber. The top portion of the insulating material 118 may have a curved recess due to the bombardment of ions. In some embodiments, the modified second semiconductor etch process 149 is a two-step process comprising an anisotropic etching process and an isotropic etching process. The anisotropic etching process may be a plasma etch using a bromine-based (e.g., HBr) or a chlorine-based (e.g., Cl₂) etch chemistry as discussed previously with respect to the first semiconductor etch process 141 (in FIGS. 17A and 17B). The isotropic etching process may be a plasma etch using a fluorine-based (e.g., NF₃) and/or a hydrogen-based (e.g., H₂) etch chemistry. In some embodiments, a bias power is applied during both the anisotropic etching process and the isotropic etching process. In some embodiments, a bias power is applied during the anisotropic etching process and the isotropic etching process is performed without a bias power. Alternatively, the anisotropic etching process may be a dry etch process and the isotropic etching process may be a wet etch process to achieve high selective etch between the substrate 101 and the insulating material 118.

In some embodiments, the modified second semiconductor etch process 149 is a plasma-based atomic layer etching (ALE) process, which is a cyclical etching process of gas dosing and ion bombardment that removes material layer by layer with low damage to the structure. The ALE process facilitates formation of a flat top surface 101ts of the substrate 101 An exemplary ALE process may include (1) dosing of the semiconductor device structure 100 disposed in a process chamber with a halogen-based etching gas (e.g., a fluorine-based, chlorine-based, and/or bromine-based chemistry as discussed above) which absorbs on and chemically reacts with the insulating material 118 and the substrate portion forming the fin structures 102b, 102c; (2) purging of residual dose gas from the process chamber; (3) bombardment of the insulating material 118 and the substrate portion forming the fin structures 102b, 102c with low energy inert ions (e.g., argon) to remove the reacted surface layer; and (4) purging of etching by-products from the process chamber. In some embodiments, a radical-based ALE process may be used.

In some embodiments, the ALE process may use oxygen molecules or radicals to chemically react with the insulating material 118 and the substrate portion forming the fin structures 102b, 102c, and the reacted layer (e.g., SiO) is removed by HF based chemistry.

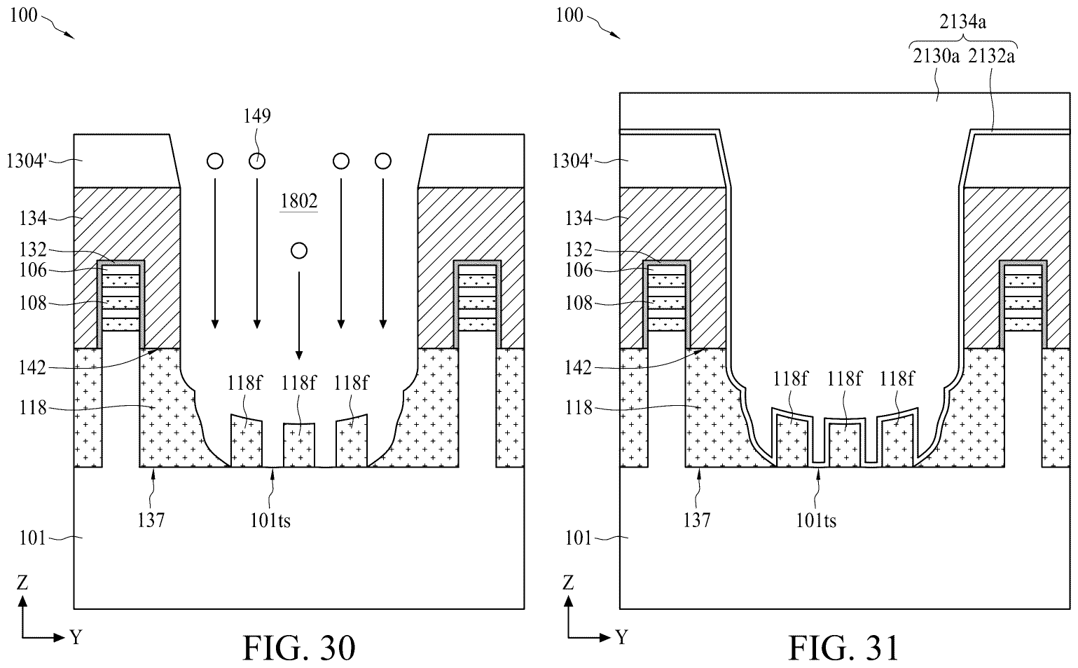

In FIG. 31, the isolation trenches 1802 (FIG. 30) are filled with a dielectric material 2130a, such as the dielectric material 2130. Likewise, a dielectric liner 2132a, such as the dielectric liner 2132, may be first disposed on exposed surfaces of the isolation trenches 1802. That is, the dielectric liner 2132a is deposited on the exposed surfaces of each fin-like structure 118f of the insulating material 118, the sidewall of the insulating material 118, the substrate 101, the sacrificial gate electrode layer 134, and the patterned mask layer 1304′. The dielectric material 2130a and the dielectric liner 2132a filled within the isolation trenches 1802 form isolation trench structures 2134a. The isolation trench structures 2134a have a plurality of fin-like insulating materials 118f on a substantially flat top surface 101ts of the substrate 101.

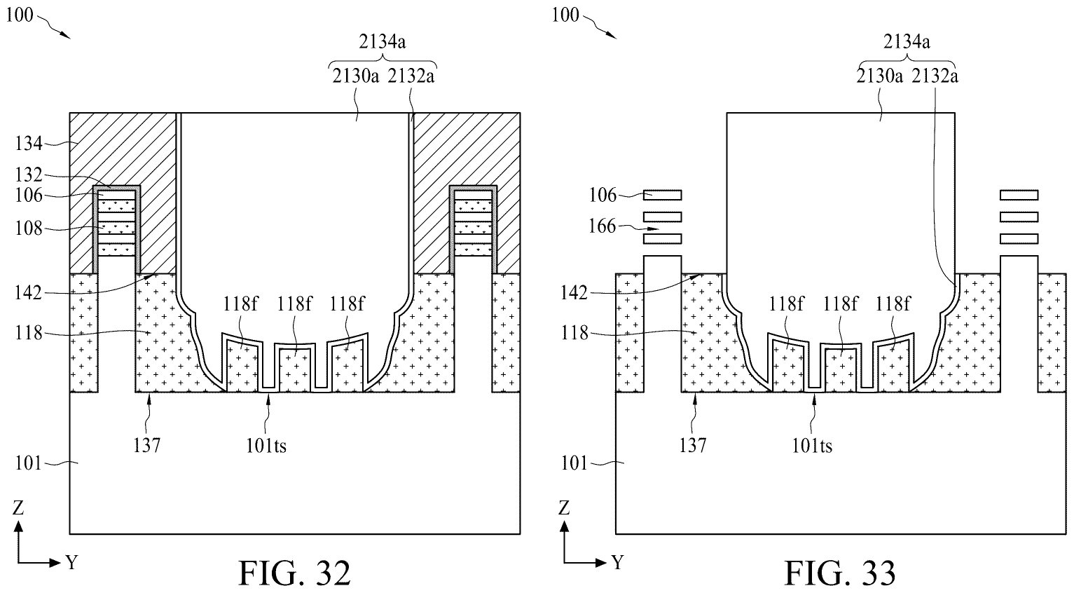

In FIG. 32, once the isolation trenches 1802 are filled, a planarization process may be performed to remove portions of the dielectric material formed over the patterned mask layer 1304′, such as those discussed above with respect to FIGS. 22A and 22B. The planarization process may be performed until a portion of the cap layer 139 or the sacrificial gate electrode layer 134 is exposed.

In FIG. 33, the sacrificial gate structures 130, the sacrificial gate dielectric layer 132, and the second semiconductor layers 108 are removed, such as those discussed above with respect to FIGS. 23A and 23B.

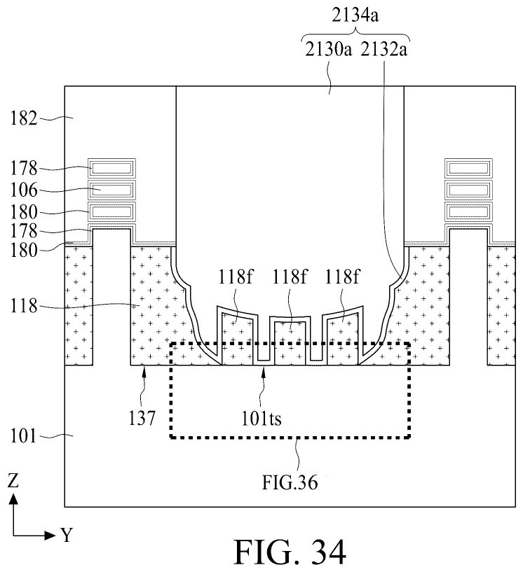

In FIG. 34, replacement gate structures are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178, the gate dielectric layer 180, and the gate electrode layer 182 may be formed in a similar fashion as those discussed above with respect to FIGS. 24A and 24B to 25A and 25B.

Portions of the gate electrode layer 182 and the gate dielectric layer 180 above the top surfaces of the first ILD layer 164 (not shown), the CESL 162 (not shown), the cap layer 139 (not shown), and the gate spacers 138 (not shown) may be removed by a planarization process. After the CMP process, the top surfaces of the isolation trench structure 2134a, the first ILD layer 164, the CESL 162, the gate spacers 138, and the gate electrode layer 182 are substantially co-planar.

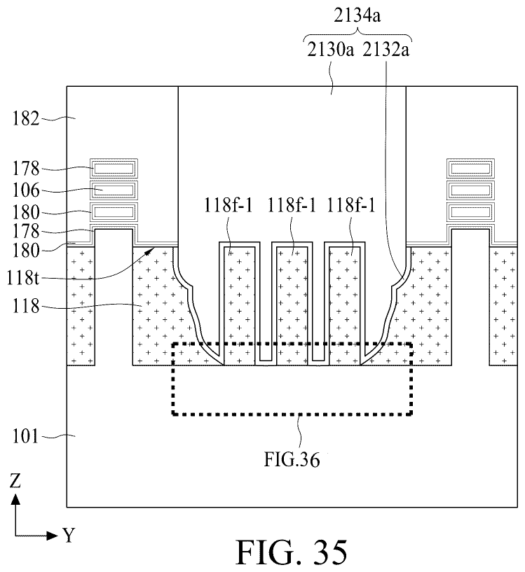

In some embodiments, the modified second semiconductor etch process 149 is configured to be a high selective etch process so that the majority of the insulating material 118 remains within the isolation trenches 1802. FIG. 35 illustrates a cross-sectional view of the semiconductor device structure 100 in accordance with an alternative embodiment where the fin-like structures 118f-1 of the insulating material 118 in the isolation trench structure 2134 have a top at substantially the same elevation as the insulating material 118 below the gate electrode layer 182.

FIG. 36 illustrates an enlarged view of a portion of the substrate 101 shown in FIGS. 34 and 35, in accordance with some embodiments. As can be seen, the top surface 101ts of the substrate 101 may include a first portion 101ts-1 that is substantially flat, and a second portion 101ts-2 that has a curved profile due to prior exposure to the etch chemistry during the modified second semiconductor etch process 149. The lowest top surface 101ts-2 of the substrate 101 is at an elevation below the interface 137 defined by the substrate 101 and the insulating material 118.

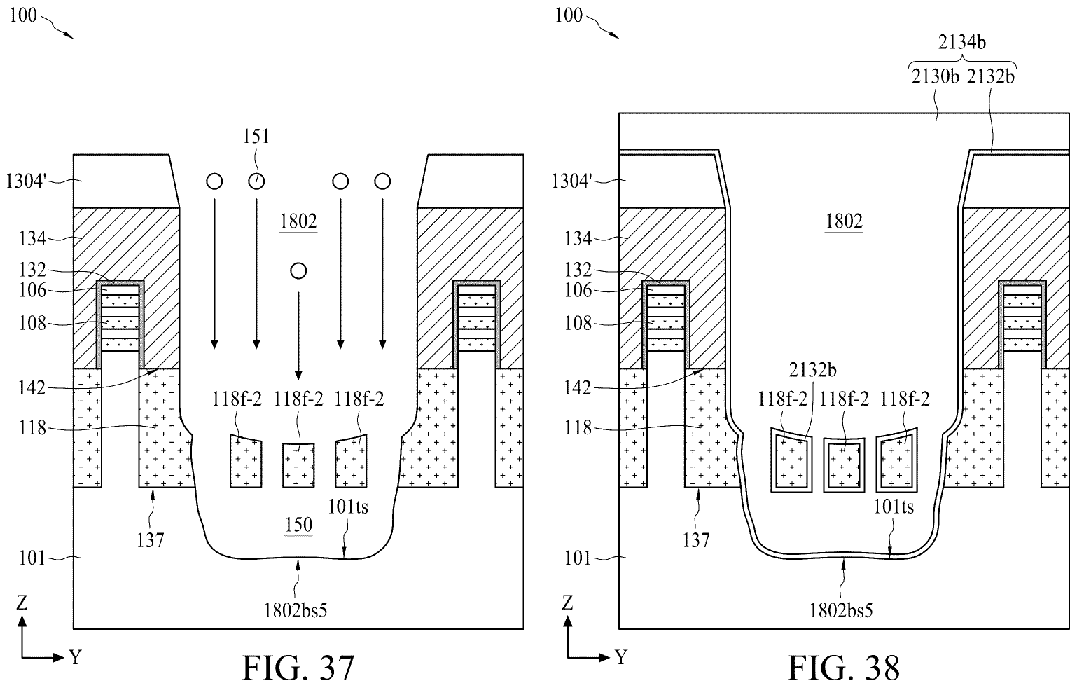

FIGS. 37-43 illustrate an alternative embodiment where a portion of insulating material 118 remains within the isolation trench structure and is disposed away from the top surface 101ts of the exposed substrate 101. In FIG. 37, after the first semiconductor etch process 141 removes the first and second semiconductor layers 106, 108 (and a small portion of the insulating material 118 in some cases), a modified second semiconductor etch process 151 is performed to further remove portions of the exposed insulating material 118, the substrate portion forming the fin structures 102b, 102c, and a portion of the exposed substrate 101. The modified second semiconductor etch process 151 is a selective etch process that selectively removes silicon (e.g., substrate portion forming the fin structures 102b, 102c and the substrate 101) over silicon oxide (e.g., insulating material 118). The modified second semiconductor etch process 151 is performed such that the bottom surface 1802bs5 of the isolation trench 1802 is at an elevation below the interface 137 defined by the substrate 101 and the insulating material 118. As a result, the insulating material 118, which is in the form of a plurality of fin-like structures 118f-2, remains within the isolation trenches 1802 and separated from the recessed substrate 101 by an opening 150. In addition, the isolation trench structure 2134a is formed to have a substantially flat bottom surface 1802bs5, such as those discussed above with respect to FIGS. 18B, 19, and 20.

Referring to FIGS. 28 and 37, the fin-like structures 118f-2 of the insulating material 118 are connected to or supported by the epitaxial source/drain features 146, which may be disposed along the X-direction (into the paper). The top of the fin-like structures 118f-2 of the insulating material 118 is at an elevation below the top surface of the insulating material 118, or an interface 142 defined by the insulating material 118 and the sacrificial gate electrode layer 134. The bottom of each fin-like structure 118f-2 of the insulating material 118 is at substantially the same elevation as the interface 137 defined by the substrate 101 and the insulating material 118.

The modified second semiconductor etch process 151 is similar to the modified second semiconductor etch process 149. In one embodiment, a two-step process comprising an anisotropic etching process and an isotropic etching process is used. The anisotropic etching process is a plasma etch using a bromine-based (e.g., HBr) etch chemistry, and the isotropic etching process is a plasma etch using a fluorine-based (e.g., NF₃) and/or a hydrogen-based (e.g., H₂) etch chemistry. To compensate for etch selectivity needed for removing the substrate 101 and the substrate portion forming the fin structures 102b, 102c, a high pressure process (e.g., chamber pressure greater than about 50 mTorr) and/or a high bias power (e.g., greater than 300 V) to the substrate pedestal may be used. In some embodiments, a high bias power is applied during the anisotropic etching process and a low bias power is used during the isotropic etching process. Alternatively, the anisotropic etching process may be a dry etch process and the isotropic etching process may be a wet etch process to achieve high selective etch between the substrate 101 and the insulating material 118.

In FIG. 38, the isolation trenches 1802 (FIG. 37) are filled with a dielectric material 2130b, such as the dielectric material 2130. Likewise, a dielectric liner 2132b, such as the dielectric liner 2132, may be first disposed on exposed surfaces of the isolation trenches 1802. That is, the dielectric liner 2132b is deposited on the exposed surfaces of each fin-like structure 118f-2 of the insulating material 118, the insulating material 118, the substrate 101, the sacrificial gate electrode layer 134, and the patterned mask layer 1304′. The dielectric material 2130bb and the dielectric liner 2132b filled within the isolation trenches 1802 form isolation trench structures 2134b. Each of the plurality of fin-like structures 118f-2 of the insulating materials 118 in the isolation trench structures 2134b is separated from the flat top surface 101ts of the substrate 101 by the dielectric material 2130 and the dielectric liner 2132.

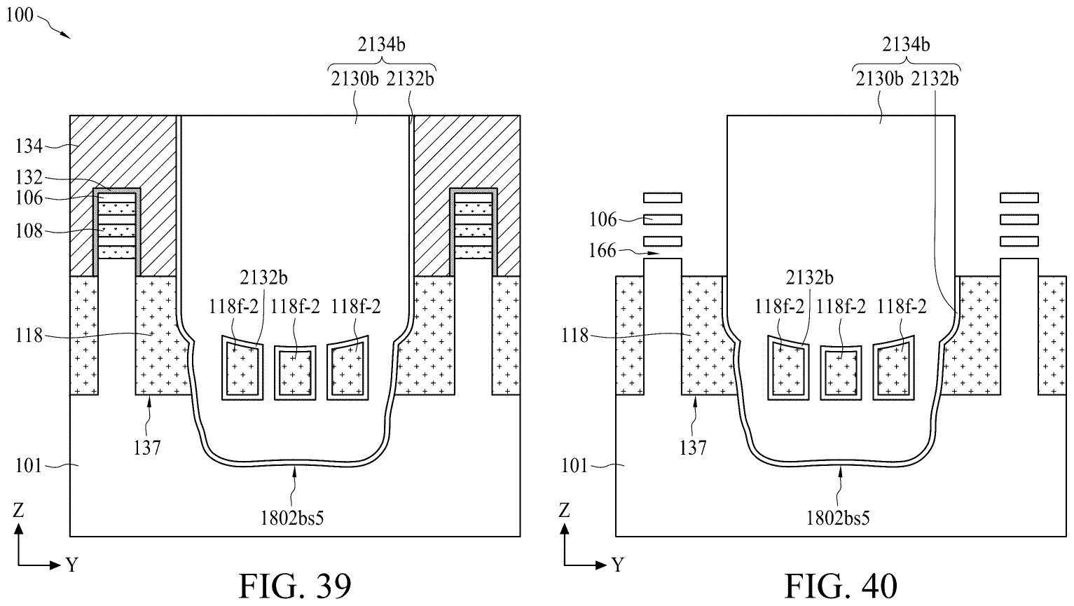

In FIG. 39, once the isolation trenches 1802 are filled, a planarization process may be performed to remove portions of the dielectric material formed over the patterned mask layer 1304′, such as those discussed above with respect to FIGS. 22A and 22B. The planarization process may be performed until a portion of the cap layer 139 or the sacrificial gate electrode layer 134 is exposed.

In FIG. 40, the sacrificial gate structures 130, the sacrificial gate dielectric layer 132, and the second semiconductor layers 108 are removed, such as those discussed above with respect to FIGS. 23A and 23B.

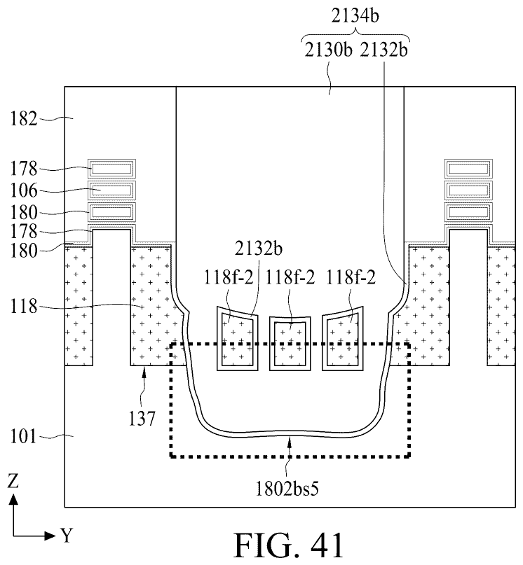

In FIG. 41, replacement gate structures are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178, the gate dielectric layer 180, and the gate electrode layer 182 may be formed in a similar fashion as those discussed above with respect to FIGS. 24A and 24B to 25A and 25B. Portions of the gate electrode layer 182 and the gate dielectric layer 180 above the top surfaces of the first ILD layer 164 (not shown), the CESL 162 (not shown), the cap layer 139 (not shown), and the gate spacers 138 (not shown) may be removed by a planarization process. After the CMP process, the top surfaces of the isolation trench structure 2134a, the first ILD layer 164, the CESL 162, the gate spacers 138, and the gate electrode layer 182 are substantially co-planar.

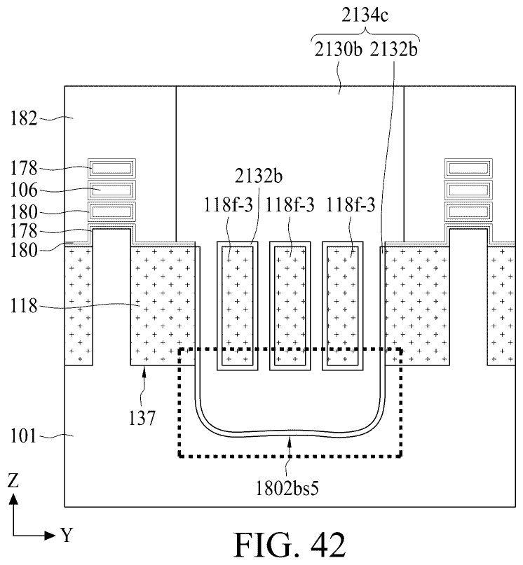

In some embodiments, the modified second semiconductor etch process 151 is configured to be a high selective etch process so that the majority of the insulating material 118 remains within the isolation trenches 1802. FIG. 42 illustrates a cross-sectional view of the semiconductor device structure 100 in accordance with an alternative embodiment. In this embodiment, the fin-like structures 118f-3 of the insulating material 118 in the isolation trench structure 2134c have a top at substantially the same elevation as the insulating material 118 below the gate electrode layer 182 (or an interface 153 defined by the IL 178 and the insulating material 118). The bottom of each fin-like structure 118f-3 of the insulating material 118 is at substantially the same elevation as the interface 137 defined by the substrate 101 and the insulating material 118.

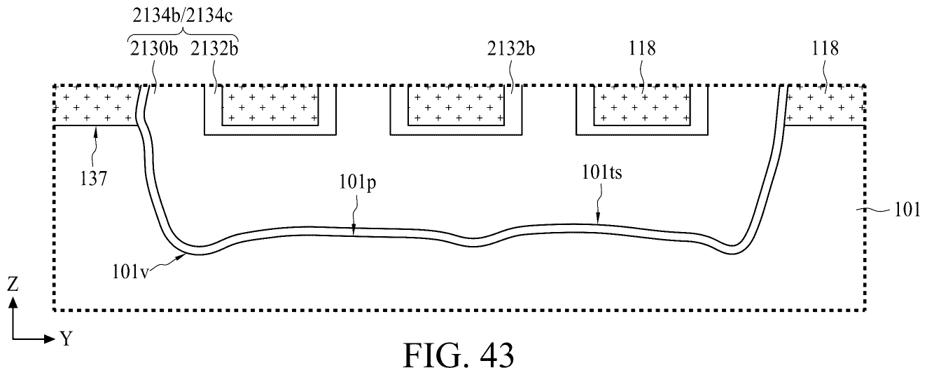

FIG. 43 illustrates an enlarged view of a portion of the substrate 101 shown in FIGS. 41 and 42, in accordance with some embodiments. As can be seen, the substrate 101 may be etched to have a peak 101p and a valley 101v, resulting in the CPODE structure with a wavy bottom surface profile.

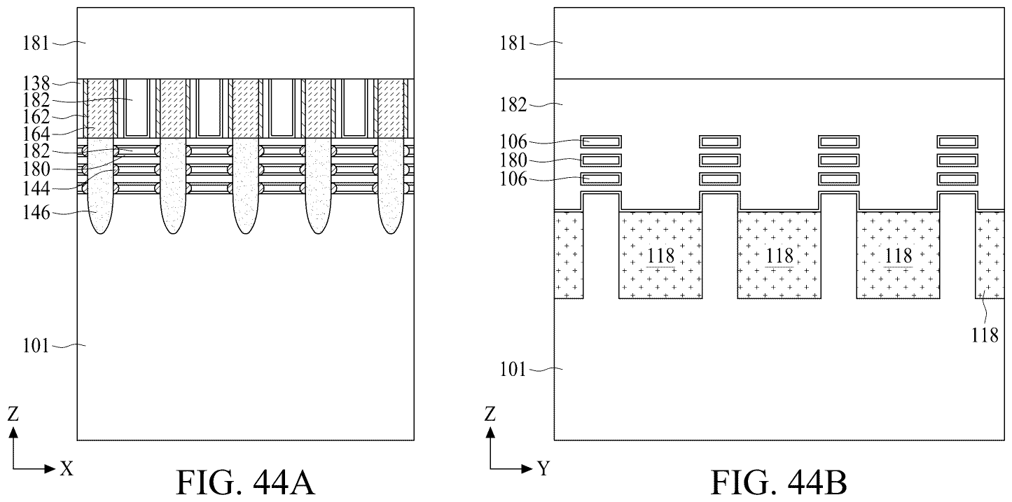

While various embodiments in FIGS. 10A-43 describe a CPODE-first processing methods, i.e., during front-end-of-line (FEOL) processing before metal gate formation, the embodiments are equally applicable to a CPODE-last processing method (or so-called CMODE process), i.e., during middle-end-of-line (MEOL) processing after metal gate formation is formed. FIGS. 44A and 44B to 49A and 49B are cross-sectional views of one of various stages of manufacturing the semiconductor device structure 100, in accordance with some embodiments involving CMODE process (i.e., after the metal gate structure is formed). In FIGS. 44A and 44B, the sacrificial gate structures 130 (FIGS. 10A and 10B), the sacrificial dielectric layer 132 (FIGS. 10A and 10B), and the second semiconductor layers 108 (FIGS. 10A and 10B) have been replaced with an IL (not shown), gate dielectric layers 180, and the gate electrode layers 182, such as those discussed above with respect to FIGS. 23A and 23B to 24A and 24B. The gate dielectric layer 180 and the gate electrode layer 182 are planarized by, for example, CMP, until the top surfaces of the ILD 164 are exposed. Then, a mask layer 181 is formed on the gate electrode layers 182, the ILD layer 164, the gate spacer 138, and the CESL 162. The mask layer 181 may include the same material as the hard mask 1304 as discussed above.

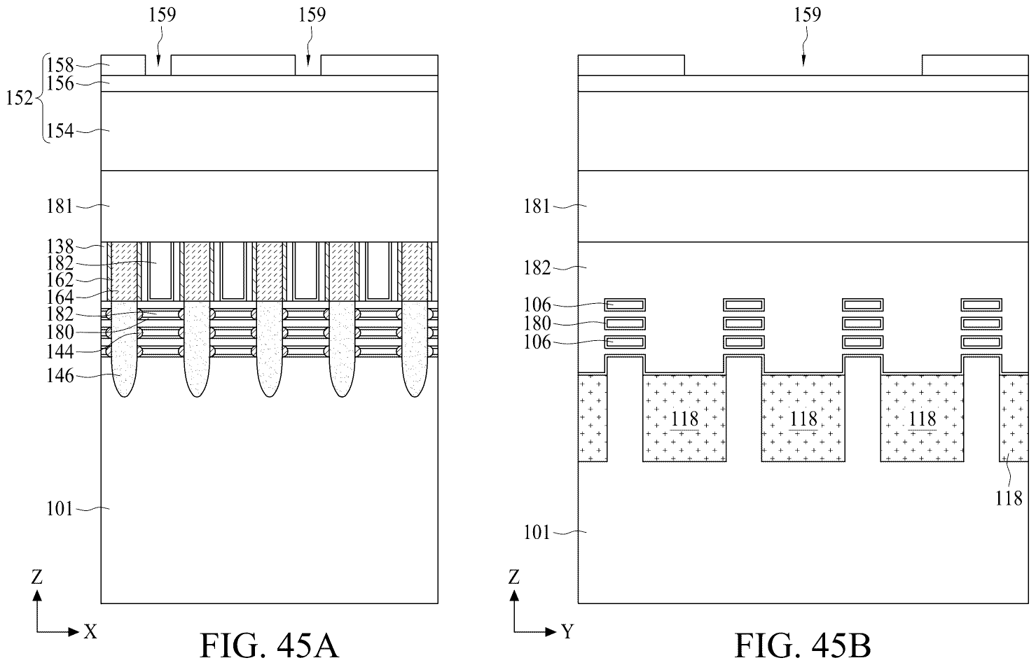

In FIGS. 45A and 45B, a mask structure 152 is formed on the mask layer 181. In some embodiments, the mask structure 152 is a tri-layer photoresist. For example, the mask structure 152 may include a bottom layer 154 and a middle layer 156 disposed on the bottom layer 154. The bottom layer 154 and the middle layer 156 are made of different materials such that the optical properties and/or etching properties of the bottom layer 154 and the middle layer 156 are different from each other. In some embodiments, the bottom layer 154 may be a carbon layer, and the middle layer 156 may be a silicon-rich layer designed to provide an etch selectivity between the middle layer 156 and the bottom layer 154. The mask structure 152 further includes a photoresist layer 158 that may be a chemically amplified photoresist layer and can be a positive tone photoresist or a negative tone photoresist. The photoresist layer 158 may include a polymer. The photoresist layer 158 may be formed by spin-on coating. The photoresist layer 158 may be patterned to have openings 159 formed therein.

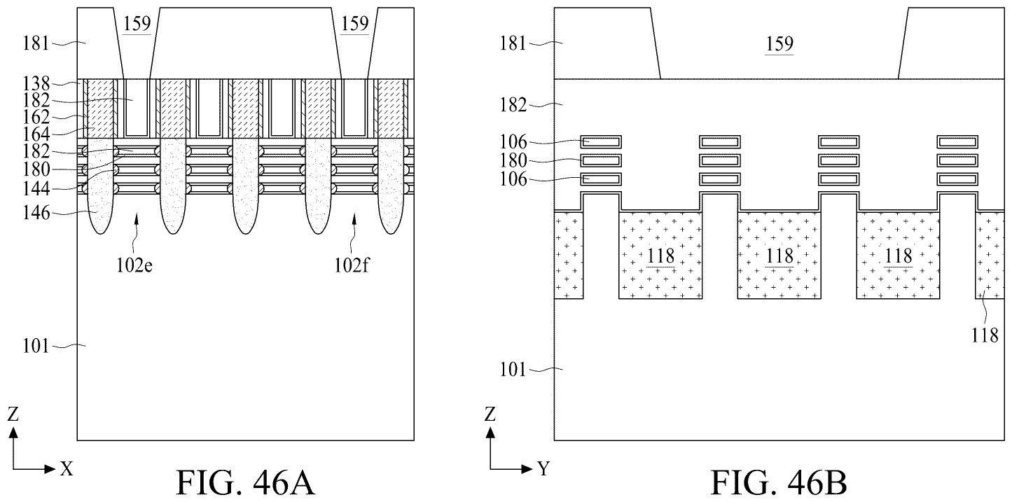

In FIGS. 46A and 46B, the openings 159 are extended into the middle layer 156, the bottom layer 154, and the mask layer 181 to expose at least portions of the gate electrode layers 182. The mask structure 152 is then removed after the openings 159 are extended into the mask layer 181.

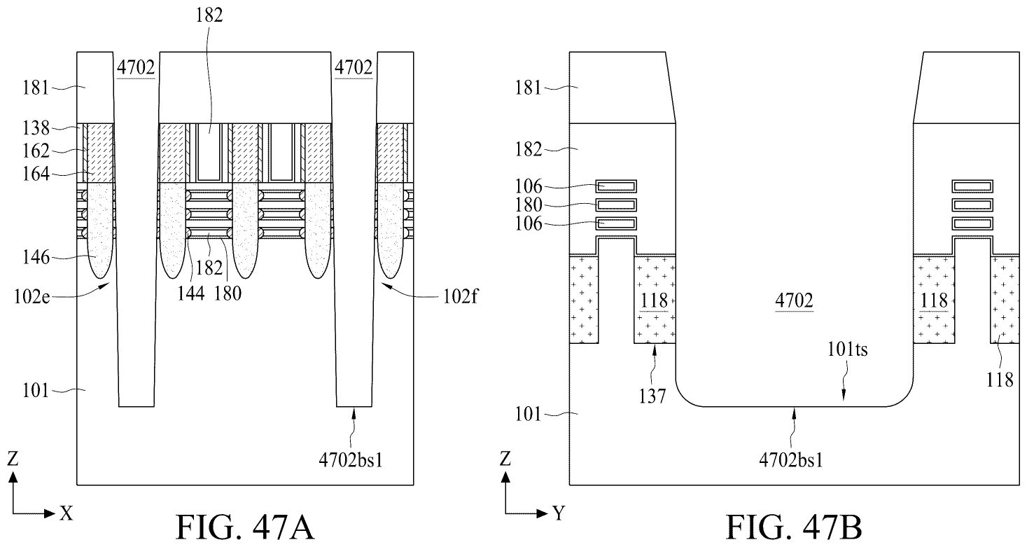

In FIGS. 47A and 47B, portions of the gate electrode layer 182, the gate dielectric layer 180, the first semiconductor layers 106, the insulating material 118, the substrate portion forming the fin structures 102e, 102f are removed using the patterned mask layer 181 as a mask. The removal of the layers may be achieved using any suitable dry etch, wet etch, or a combination thereof, such as those discussed above with respect to FIGS. 14A-20. As a result of the removal process(es), isolation trenches 4702 are formed. The isolation trenches 4702 are etched to have a bottom 4702bs1 extending a depth into the well region of the substrate 101. Such recess of the substrate 101 may be obtained by controlling one or more etch conditions to achieve low selectivity etch between silicon (e.g., substrate 101) and silicon oxide (e.g., insulating material 118). For example, a low-pressure process (e.g., chamber pressure below about 50 mTorr) and/or high bias power to the substrate pedestal (e.g., greater than 300 V) may be utilized during the removal process to compensate for etch selectivity needed for removing the insulating material 118 and the substrate portion of the fin structures 102e, 102f.

In some embodiments, the isolation trenches 4702 are etched such that the bottom surface 4702bs1 of the isolation trenches 4702, or stated differently, a top surface 101ts of the exposed substrate 101, is substantially flat. In one embodiment, the bottom surface 4702bs1 is at an elevation below an interface 137 defined by the substrate 101 and the insulating material 118. As discussed above, the substrate 101 with a flat top surface 101ts does not form a parasitic bipolar junction transistor in the well region, which may lead to formation of EPI-substrate-EPI leakage path.

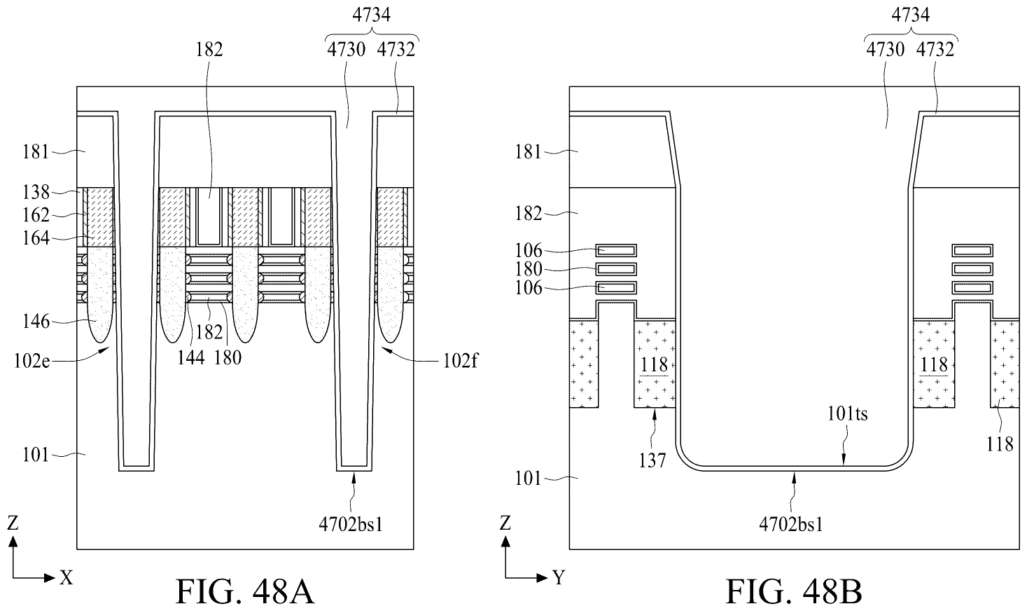

In FIGS. 48A and 48B, the isolation trenches 4702 (FIGS. 47A and 47B) are filled with a dielectric material 4730, such as the dielectric material 2130. Likewise, a dielectric liner 4732, such as the dielectric liner 2132, may be first disposed on exposed surfaces of the isolation trenches 4702. That is, the dielectric liner 4732 is deposited on the exposed surfaces of the insulating material 118, the substrate 101, the gate electrode layer 182, and the patterned mask layer 181. The dielectric material 4730 and the dielectric liner 4732 filled within the isolation trenches 4702 form isolation trench structures (so-called CMODE structures) 4734. The isolation trench structures 4734 has a substantially flat bottom surface corresponding to the top surface 101ts of the substrate 101.

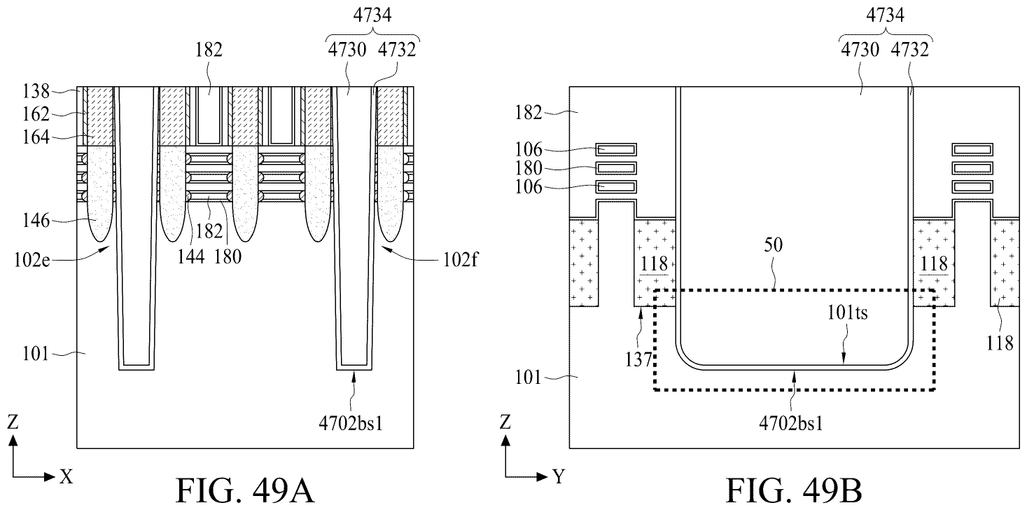

In FIGS. 49A and 49B, once the isolation trenches 4702 are filled, a planarization process may be performed to remove portions of the dielectric material formed over the patterned mask layer 181, such as those discussed above with respect to FIGS. 22A and 22B. The planarization process may be performed until the ILD 164 is exposed. After the planarization process, the top surfaces of the dielectric material 4730, the dielectric liner 4732, the gate electrode layer 182, the ILD layer 164, the gate spacer 138, and the CESL 162 are substantially co-planar.

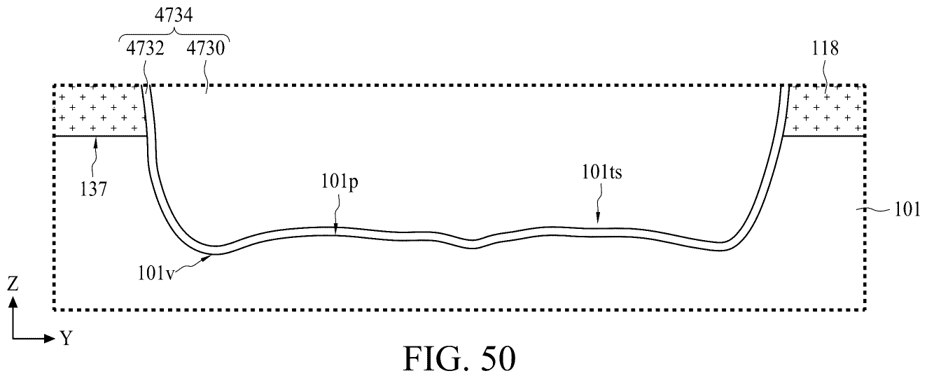

FIG. 50 is an enlarged view of a portion of the substrate 101 shown in FIG. 49B, in accordance with some embodiments. As can be seen, the substrate 101 may be etched to have a peak 101p and a valley 101v, resulting in the CMODE structure 4734 with a wavy bottom surface profile.

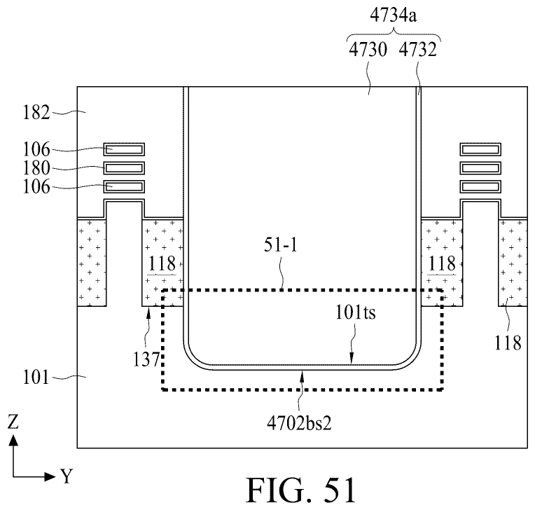

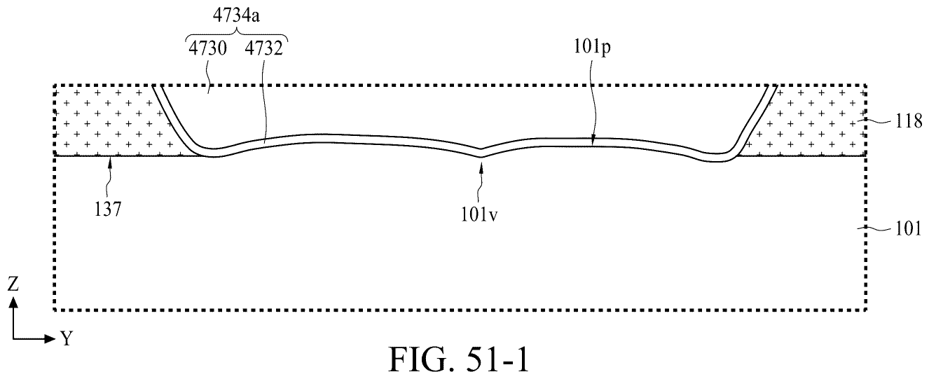

FIG. 51 illustrates an embodiment where the isolation trench structures (CMODE structures) 4734a have a bottom 4702bs2 at substantially the same elevation as the top surface 101ts of the substrate 101. In this embodiment, the substrate 101 may be etched using any suitable dry etch, wet etch, or a combination thereof, such as those discussed above with respect to FIGS. 14A-18B.

FIG. 51-1 illustrates an enlarged view of a portion of the substrate 101 shown in FIG. 51, in accordance with some embodiments. As can be seen, the substrate 101 may be etched to have a peak 101p and a valley 101v, resulting in the CMODE structures with a wavy bottom surface profile.

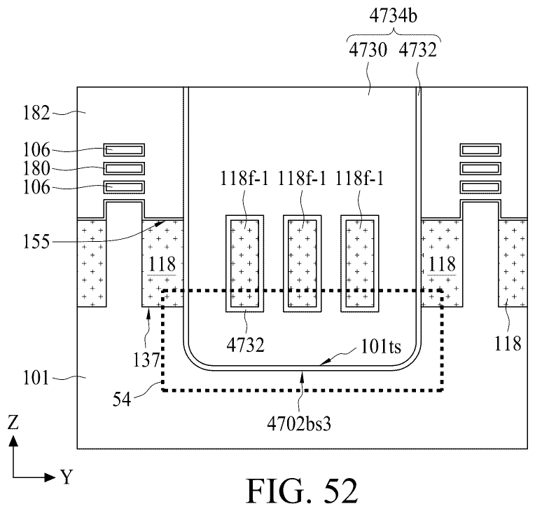

FIG. 52 illustrates a cross-sectional view of the semiconductor device structure 100 in accordance with an alternative embodiment. In this embodiment, the isolation trench structures (CMODE structures) 4734b have a substantially flat bottom surface 4702bs3 at an elevation below an interface 137 defined by the substrate 101 and the insulating material 118. Particularly, a plurality of fin-like structures 118f-4 of the insulating material 118 remains in the isolation trench structure 4734b. While not shown, the fin-like structures 118f-4 of the insulating material 118 are connected to or supported by the epitaxial source/drain features 146, which may be disposed along the X-direction (into the paper). Each of the fin-like structure 118f-4 of the insulating material 18 has a top at substantially the same elevation as an interface 155 defined by the gate dielectric layer 180 and the insulating material 118 below the gate electrode layer 182. The fin-like structures 118f-4 of the insulating material 118 may be formed by any suitable processes, such as those discussed above with respect to FIGS. 37-43.

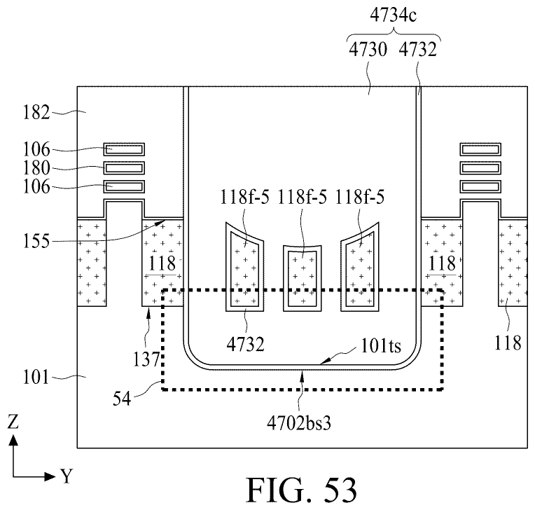

FIG. 53 illustrates a cross-sectional view of the semiconductor device structure 100 in accordance with an alternative embodiment. The embodiment of FIG. 53 is substantially identical to that of FIG. 52 except that fin-like structures 118f-5 of the insulating material 118 in the isolation trench structure 4734b have a top at an elevation lower than the interface 155 defined by the gate dielectric layer 180 and the insulating material 118 below the gate electrode layer 182. The bottom of each fin-like structure 118f-5 of the insulating material 118 is at substantially the same elevation as the interface 137 defined by the substrate 101 and the insulating material 118.

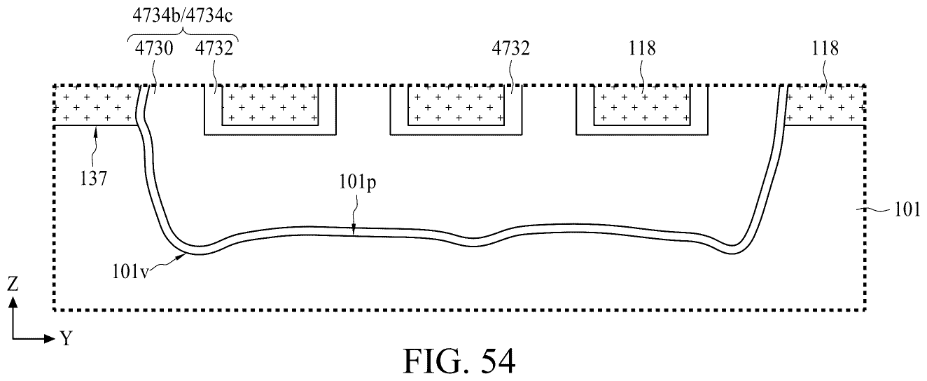

FIG. 54 illustrates an enlarged view of a portion of the substrate 101 shown in FIGS. 52 and 53, in accordance with some embodiments. As can be seen, the substrate 101 may be etched to have a peak 101p and a valley 101v, resulting in the CMODE structures with a wavy bottom surface profile.

Embodiments of the present disclosure provide improved isolation trench structures (e.g., CPODE/CMODE structures) having a substantially flat bottom surface in contact with a top surface of the substrate. The isolation trench structure with a flat bottom surface prevents the top surface of the substrate from forming fin-like structures and becoming parasitic bipolar junction transistors (BJTs). In some cases, the isolation trench structure may extend into the well region of the substrate to block leakage current through EPI-transistors-substrate-EPI.

A semiconductor device structure is described. The structure includes a substrate, an insulating material disposed on the substrate, a first fin structure extending upwardly from the substrate through the insulating material, a second fin structure extending upwardly from the substrate through the insulating material, wherein the first and second fin structures extend along a first direction. The structure further includes an isolation trench structure disposed between the first and second fin structures, the isolation trench structure extending along a second direction perpendicular to the first direction, wherein the isolation trench structure has a bottom in contact with a top surface of the substrate, and the bottom of the isolation trench structure and the top surface of the substrate define an interface that is substantially flat.

Another embodiment is a semiconductor device structure. The structure includes a substrate, an insulating material disposed on the substrate, wherein the insulating material and a first portion of the substrate define a first interface. The structure also includes a first fin structure extending upwardly from the substrate through a first portion of the insulating material, a second fin structure extending upwardly from the substrate through a second portion of the insulating material, and an isolation trench structure disposed between the first and second fin structures, wherein at least portions of the isolation trench structure are separated from each other by a third portion of the insulating material.

A further embodiment is a method for forming a semiconductor device structure. The method includes forming a first fin structure and a second fin structure from a substrate, each first and second fin structure comprises a plurality of first semiconductor layers and a plurality of second semiconductor layers alternatingly stacked. The method also includes forming an insulating material on the substrate, forming a metal gate structure on the insulating material and over a portion of each of first and second fin structures, removing a portion of the metal gate structure over the first and second fin structures, removing the first and second fin structures, portions of the insulating material, and the substrate by one or more etch processes to form an isolation trench with a substantially flat bottom surface extending between opposite sidewalls of the isolation trench, and filling the isolation trench with a dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate;
an insulating material disposed on the substrate;
a first fin structure extending upwardly from the substrate through the insulating material;
a second fin structure extending upwardly from the substrate through the insulating material, the first and second fin structures extending along a first direction; and
an isolation trench structure disposed between the first and second fin structures, the isolation trench structure extending along a second direction perpendicular to the first direction,
wherein the isolation trench structure has a bottom in contact with a top surface of the substrate, and the bottom of the isolation trench structure and the top surface of the substrate define an interface that is substantially flat.

2. The semiconductor device structure of claim 1, wherein the insulating material and the substrate define a second interface, and the first interface is at substantially the same elevation as the second interface.

3. The semiconductor device structure of claim 1, wherein the insulating material and the substrate define a second interface, and the first interface is at an elevation lower than the second interface.

4. The semiconductor device structure of claim 1, wherein the isolation trench structure further comprising:
a plurality of fin-like structures disposed on the substrate, wherein the plurality of fin-like structures and the insulating material are formed from the same material.

5. The semiconductor device structure of claim 4, wherein a top of one or more of the plurality of the fin-like structures is at an elevation below a top surface of the insulating material.

6. The semiconductor device structure of claim 4, wherein a top of one or more of the plurality of the fin-like structures is at substantially the same elevation as a top surface of the insulating material.

7. The semiconductor device structure of claim 4, wherein each of the plurality of fin-like structures is connected to or supported by an epitaxial source/drain feature.

8. A semiconductor device structure, comprising:
a substrate;
an insulating material disposed on the substrate, the insulating material and a first portion of the substrate defining a first interface;
a first fin structure extending upwardly from the substrate through a first portion of the insulating material;
a second fin structure extending upwardly from the substrate through a second portion of the insulating material; and
an isolation trench structure disposed between the first and second fin structures, wherein at least portions of the isolation trench structure are separated from each other by a third portion of the insulating material.

9. The semiconductor device structure of claim 8, wherein the third portion of the insulating material comprises a plurality of fin-like structures.

10. The semiconductor device structure of claim 8, wherein a bottom of the isolation trench structure and a second portion of the substrate define a second interface lower than the first interface.

11. The semiconductor device structure of claim 9, wherein each of the fin-like structures is surrounded by a dielectric liner.

12. The semiconductor device structure of claim 10, wherein the third portion of the insulating material is separated from the second portion of the substrate by the isolation trench structure.

13. The semiconductor device structure of claim 10, wherein the third portion of the insulating material has a top at a third elevation, and the third elevation is at substantially the same elevation as the first interface.

14. The semiconductor device structure of claim 10, wherein the third portion of the insulating material has a top at a third elevation, and the third elevation is at an elevation below the first interface.

15. The semiconductor device structure of claim 10, wherein the bottom of the isolation trench structure has a wavy profile.

16. The semiconductor device structure of claim 10, wherein the bottom of the isolation trench structure has a substantially flat profile.

17. A method for forming a semiconductor device structure, comprising:
forming a first fin structure and a second fin structure from a substrate, each first and second fin structure comprises a plurality of first semiconductor layers and a plurality of second semiconductor layers alternatingly stacked;
forming an insulating material on the substrate;
forming a metal gate structure on the insulating material and over a portion of each of first and second fin structures;
removing a portion of the metal gate structure over the first and second fin structures;
removing the first and second fin structures, portions of the insulating material, and the substrate by one or more etch processes to form an isolation trench with a substantially flat bottom surface extending between opposite sidewalls of the isolation trench; and
filling the isolation trench with a dielectric material.

18. The method of claim 17, wherein the bottom surface of the isolation trench is at an elevation below an interface defined by the substrate and the insulating material.

19. The method of claim 17, wherein the one or more etch processes are performed so that portions of the insulating material in the form of fin-like structure remain within the isolation trench.

20. The method of claim 19, wherein each portion of the insulating material in the form of fin-like structure is surrounded by a dielectric liner.
